(19) United States
(12) Patent Application Publication
(10) Pub. No.: US 2026/0299023 A1
(43) Pub. Date: Oct. 1, 2026

(54) TESTING LARGE-SCALE ELECTRONIC SYSTEMS CONSTITUTED OF MANY FUNCTIONAL BLOCKS

(71) Applicant: Krivya Semicon Private Limited, Bangalore (IN)

(72) Inventor: Kamlesh Kumar Sureshchandra Pandey, Bangalore (IN)

(21) Appl. No.: 19/227,539

(22) Filed: Jun. 4, 2025

(30) Foreign Application Priority Data
Mar. 31, 2025 (IN) 202541031788

(51) Int. Cl. G01R 31/319; G01R 31/3183; G01R 31/3185

(52) U.S. Cl. CPC G01R 31/31908; G01R 31/3183; G01R 31/318561

(57) ABSTRACT

An electronic system with multiple functional blocks contains multiple slave units, with each functional block being connected to one of the slave units. The electronic system contains a master processor to receive test instructions and data units as a basis for multiple tests from a test equipment. The test equipment indicates a corresponding slave unit to which each test is directed to, and the master processor is designed to forward test instructions and each data unit corresponding to each of the multiple tests to a respective slave unit as indicated by the test equipment. Each slave unit is designed to execute the corresponding test(s) on the connected functional block.

### PRIORITY CLAIM

The instant patent application is related to and claims priority from the co-pending India provisional patent application entitled, “Testing large scale electronic systems constituted of many functional blocks”, Serial No.: 202541031788, Filed: 31 Mar. 2025, Attorney docket no.: KRIV-001-INPR, which is incorporated in its entirety herewith to the extent not inconsistent with the description herein.

### BACKGROUND

### Technical Field

Embodiments of the present disclosure relate generally to testing of integrated circuits (ICs), and more specifically to testing large scale electronic systems constituted of many functional blocks.

### Related Art

Electronic systems generally contain one or more integrated circuits (ICs), with each IC typically being fabricated on a single semiconductor die. The die is encapsulated in a package and pertinent internal circuit nodes are made accessible via pins (of the package) for handling and integration (typically involving mounting on printed circuit boards) with other ICs, power supplies, signal connections to I/O devices, etc., for forming a larger system, etc., as is well known in the relevant arts.

A single IC often is in the form of a SOC (system-on-chip) containing most or all of the circuit components required for realizing an end product (such as a mobile phone, medical devices, etc.). However, with the need for denser circuitry and/or processing/storage capacity, multiple dies or SOCs can be stacked and encapsulated in one or more packages, potentially soldered to a PCB (printed circuit board). In general, the technology permits electronic systems (realized as respective packages/ICs) to contain fairly complex and comprehensive circuits to address corresponding needs in the industries.

There is a general need to test such electronic systems. Testing may be viewed as primarily containing functional testing and structural testing. As is well known, a functional test is designed to check whether the electronic system under test performs each of the desired operations (e.g., computations) as intended. Thus, performance of a typical functional test entails sending to, or initializing the, appropriate input elements (e.g., registers) to test input values, and comparing the output of computation with the expected values for accuracy. The tests may be repeated for various values of clock frequencies, delays, power supply values, etc., as specified by designers of the electronics systems (or portions thereof that are of interest).

On the other hand, structural testing is performed to check various connection errors (e.g., stuck-at faults), or in general for detection of faults due to problems in the manufacturing processes that would adversely affect the functional behavior of the electronic system. Thus, structural testing attempts to uncover any defects in the underlying components and interconnect within a circuit/IC.

A functional block is a basic unit of testing in that tests are performed on individual functional blocks, i.e., inputs are provided from automated testing equipment (ATE) to the block and outputs examined at the block-level. Accordingly, each functional block contains circuitry for performing various desired functional operations (e.g., for various computations), in addition to additional circuitry to facilitate testability (also known as design for testability or DFT). For example, a functional block may contain memory elements that can be connected as a chain starting at a test input pin/node and ending at a test output pin/node, such that specific memory elements of the functional block can be set to desired values for testing and the output data examined for accuracy of operation.

At least in view of the increasing scale and complexities noted above, an electronic system may contain a large number of such functional blocks, and is accordingly termed as large-scale electronic system. Aspects of the present disclosure are directed to testing of such large-scale electronic systems containing many functional blocks.

### BRIEF DESCRIPTION OF THE VIEWS OF DRAWINGS

Example embodiments of the present disclosure will be described with reference to the accompanying drawings briefly described below.

FIG. 1 is a block diagram illustrating the manner in which an electronic system (SOC) is tested using an ATE, in an embodiment of the present disclosure.

FIG. 2 is a block diagram illustrating the internal architecture of an SOC, permitting testing in an embodiment of the present disclosure.

FIG. 3 is a block diagram illustrating the details of a master processor in a SOC, in one embodiment.

FIG. 4 is a block diagram illustrating the details of a slave unit in a SOC, in one embodiment.

FIG. 5 is a block diagram illustrating the manner in which a SOC with many functional blocks can be tested using multiple slave units, in an embodiment.

FIG. 6 is a block diagram illustrating the manner in which multiple SOCs can be tested together, in an embodiment.

FIG. 7 depicts the packet structure for communication between an ATE and the master/slave components, in an embodiment.

FIG. 8 is a diagram illustrating the details of packets sent to test multiple functional blocks, in an embodiment.

FIG. 9 is a diagram illustrating the details of packets sent to test multiple functional blocks, in another embodiment.

FIG. 10 is a state transition diagram of a portion of a master processor, in an embodiment.

FIG. 11 is a diagram illustrating the implementation of sequentially-connected slave ID registers of slave units in an embodiment.

FIG. 12 is a timing diagram illustrating the configuration of a master processor in an embodiment.

FIG. 13 is a timing diagram illustrating the programming of slave ID register of a slave unit in an embodiment.

FIG. 14 is a timing diagram illustrating the selection of a slave unit for configuration in an embodiment.

FIG. 15 is a diagram illustrating the configuration of a slave unit in an embodiment.

FIG. 16 is a diagram illustrating an example test on a pair of slave units in an embodiment.

FIG. 17 is a block diagram illustrating the manner in which test patterns for a test are generated in an ATE in an embodiment.

FIG. 18 is a block diagram illustrating the details of a digital processing system representing an ATE, in an embodiment.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

According to an aspect of the present disclosure, an electronic system containing multiple functional blocks contains multiple slave units, with each functional block being connected to one of the slave units. The electronic system contains a master processor to receive test instructions and data units as a basis for multiple tests from a test equipment. The test equipment indicates a corresponding slave unit to which each test is directed to, and the master processor is designed to forward test instructions and each data unit corresponding to each of the multiple tests to a respective slave unit as indicated by the test equipment. Each slave unit is designed to execute the corresponding test(s) on the connected functional block.

According to another aspect, tests are performed concurrently on potentially all functional blocks connected to respective slave units.

According to yet another aspect, the slave units are connected sequentially in the form of a daisy chain, starting from and ending at the master unit.

According to one more aspect, the electronic system may contain multiple systems-on-chip (SOCs), with each SOC having an associated master and set of slave units (coupled to respective functional blocks). Tests are potentially performed concurrently across SOCs as well, such that tests can be performed concurrently across all the functional blocks in the electronic system.

According to an aspect, the masters are also coupled sequentially in a second daisy chain (in combination with the slave units being connected in respective daisy chains), with the effect that the number of electrical traces (physical connections) is optimized in the electronic system.

According to one more aspect, each master receives a sequence of instructions for a test, and the master generates multiple commands to the corresponding slave(s) in response to each instruction. As a result, the implementation of all slave units is simplified. In addition, the physical (e.g., number of pins) and protocol interfaces between an Automated Test Equipment (ATE) and the SOC(s)/master(s) is also simplified.

According to yet another aspect, each of master and slave are configurable to operate in bypass-modes, to reduce power consumption when the master or slave is not part of tests being conducted (on corresponding functional blocks).

According to an aspect, the ATE generates identifiers of all slaves dynamically and configures each slave with assigned slave identifier. The configuration is used as a basis to address each slave during additional configuration before starting of a test.

Several aspects of the present disclosure are described below with reference to examples for illustration. However, one skilled in the relevant art will recognize that the disclosure can be practiced without one or more of the specific details or with other methods, components, materials and so forth. In other instances, well known structures, materials, or operations are not shown in detail to avoid obscuring the features of the disclosure. Furthermore, the features/aspects described can be practiced in various combinations, though only some of the combinations are described herein for conciseness.

### 2. Example Environment

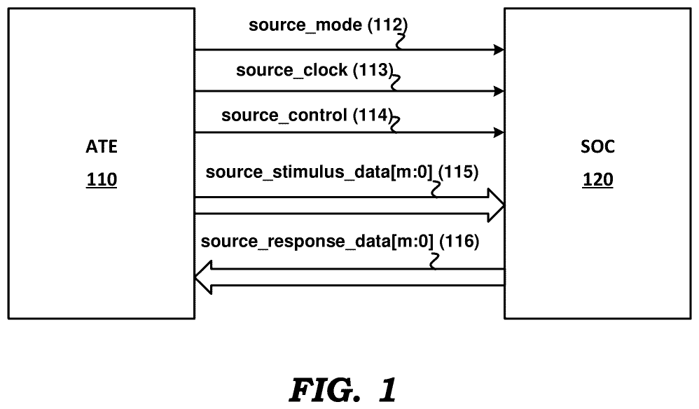

FIG. 1 is a block diagram illustrating the manner in which an electronic system is tested using an ATE, in an embodiment of the present disclosure. The diagram is shown containing Automated Test Equipment/System Level Tester (ATE) 110 used to test SOC 120 containing many functional blocks according to features of the present disclosure.

ATE 110 is designed to configure portions of SOC 120 for testing, and to issue instructions and test data to test SOC 120 for executing the tests in accordance with aspects of the present disclosure. SOC 120 represents an example electronic system that is to be tested using ATE 110. SOC 120 is implemented with additional components/circuits/blocks that facilitate interfacing with test equipment such as ATE 110 and testing functional blocks that implement the functions that the SOC is designed to provide, according to aspects of the present disclosure. The additional components/circuits/blocks implemented for testing purposes are together conveniently referred to herein generally as UTN (universal test network or simply test network). In the description below, each SOC under test is described as containing a corresponding UTN. Thus, when an electronic system to be tested contains multiple SOCs, a corresponding number of UTNs are deemed to be present as well.

In the depicted embodiment, ATE 110 is shown interfacing with SOC 120 using paths 112 (source_mode), 113 (source_clock), 114 (source_control), 115 (source_stimulus_data[m:0]) and 116 (source_response_data[m:0]), which are described in further detail below. However, it should be appreciated that a different set of signals can be used for testing, without departing from the scope and spirit of the present disclosure, as will be apparent to a skilled practitioner. Similarly, while the description below contains an example implementation of UTN, alternative designs consistent with any such different interfaces also will be apparent to a skilled practitioner by reading the disclosure provided herein.

The descriptions of the signals on the interface paths 112-116 are provided in TABLE 1 below.

TABLE 1

| | | Bit- | |
|---|---|---|---|
| Pin name | Direction | Width | Description |
| source_mode | input to | 1 | When set to 1 this signal |
| (112) | SOC 120 | | enables functionality of |
| | | | UTN. When set to 0, |
| | | | components of UTN are |
| | | | forced into (and held in) |
| | | | reset state for normal (non- |
| | | | test) operation of SOC 120. |
| source_clock | input to | 1 | Clock input for interfacing |
| (113) | SOC 120 | | with UTN (Example |
| | | | frequency range of this |
| | | | clock: 100 MHz to |
| | | | 250 MHz. |
| source_control | input to | 1 | This signal is used for |
| (114) | SOC 120 | | loading a new instruction, |
| | | | starting and stopping a test |
| | | | execution, inserting desired |
| | | | wait periods between two |
| | | | instructions and |
| | | | synchronizing multiple |
| | | | UTNs at system level. |
| source_stimulus_data | input to | M | Bus for receiving |
| (115) | SOC 120 | | instructions, stimulus data |
| | | | and configuration data. |
| | | | M can be, for example, |
| | | | between 1 and 32. |
| source_response_data | output | M | Response data bus. |
| (116) | from | | M can be, for example, |
| | SOC 120 | | between 1 and 32. |

The description is continued with respect to the details of SOC 120 operating in accordance with the signals noted above in Table 1.

### 3. Test Network Components in a SOC

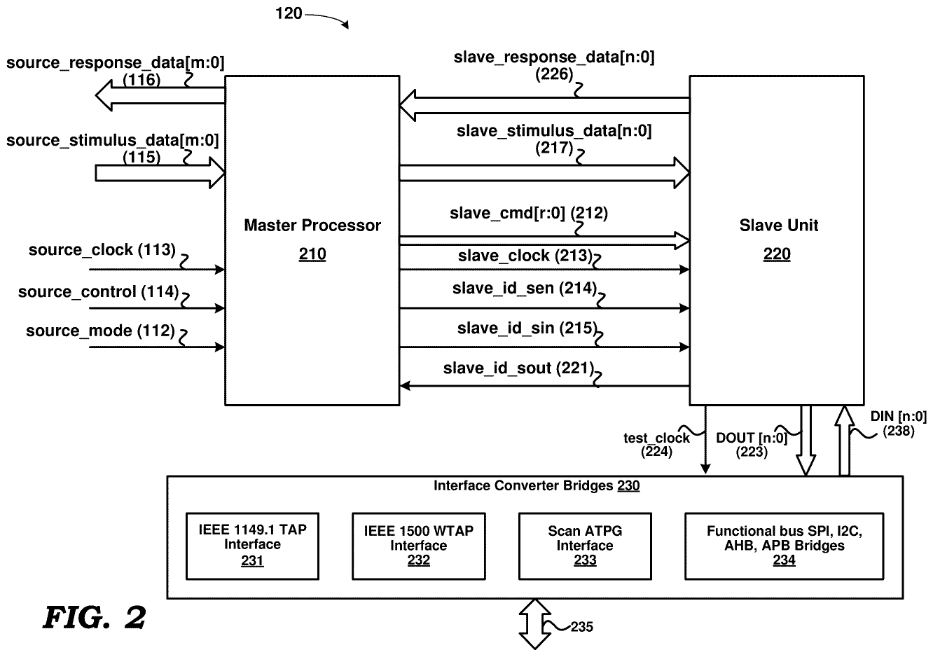

FIG. 2 is a block diagram illustrating the internal architecture of an SOC, permitting testing in an embodiment of the present disclosure. SOC 120 is shown containing UTN components master processor (master) 210, slave unit (slave) 220 and interface-converter-bridges (bridges) 230. Merely for ease of introduction, only a single UTN slave is shown in SOC 120 of FIG. 2. SOCs typically contain multiple functional blocks, and therefore would need many slave units, each one for driving a respective functional block. The functional block corresponding to slave 220 is not shown in FIG. 2, but would be interfaced to slave 220 via bridges 230. When multiple slave units are present in a single SOC, as well as when multiple such SOCs constitute the electronic system, the various components of the UTN and their interconnections and operation are described in sections below.

Master 210 is the gateway to SOC 120 from ATE 110, as confirmed by coupling of signals 112-116 as depicted. In other words, ATE 110 communicates and interacts with the slave units, as well as the functional blocks in SOC 120 that are to be tested, via master 120. There is only one master processor within each SOC that is implemented to contain the UTN. Thus, master 210 interfaces between ATE 10 and slave units in SOC 120.

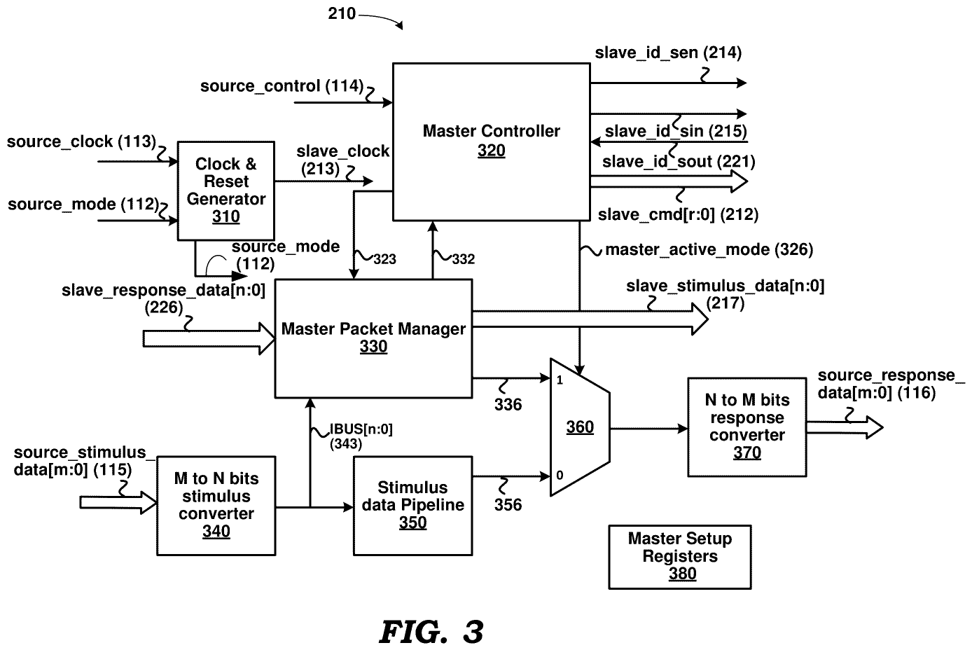

Specifically, master 210 receives instructions and data units (both configuration data as well as stimulus data) on path 115) from ATE 110 corresponding to each test to be performed using ATE 110. The term ‘packet’ is used herein to generically refer to instructions as well as data units. Master 210 forwards (or issues) corresponding commands (to implement the test) on path 212 as well as data units on path 215 to the respective slave units as indicated by ATE 110. The details of how such forwarding is achieved are described below. The internal blocks of master 210 as well as their interconnection and operation, in an embodiment, are described below with reference to FIG. 3.

As described in sections below, ATE 110 first configures master 210 in preparation for the tests to be performed on SOC 120. Subsequently, ATE 110 issues instructions and data to master 210 for causing master 210 to configure slave 220 as well as to assign to an ID to salve 220. It is noted here that when multiple slaves are present in an SOC, ATE 110 would, via master 210, configure all the slaves and assign IDs to each slave. Subsequently, ATE 110 issues instructions and test data for executing the tests.

Slave 220 provides the interface between master 210 and a corresponding functional block that is to be tested. More specifically, once configured appropriately, slave 220 receives commands and test data from ATE 110 via master 210. Based on the specific type of test (e.g., functional or structural test, type of structural test, etc.), slave 220 issues corresponding commands (or forwards the received commands) and test data to the corresponding interface contained in bridges 230 on path DOUT (223). Slave 220 receives response data on path DIN (238) from the functional block via the corresponding interface in bridges 230 as response to the test performed. The data on DOUT and DIN are synchronously transferred with respect to test_clock (224), which is generated by slave 220.

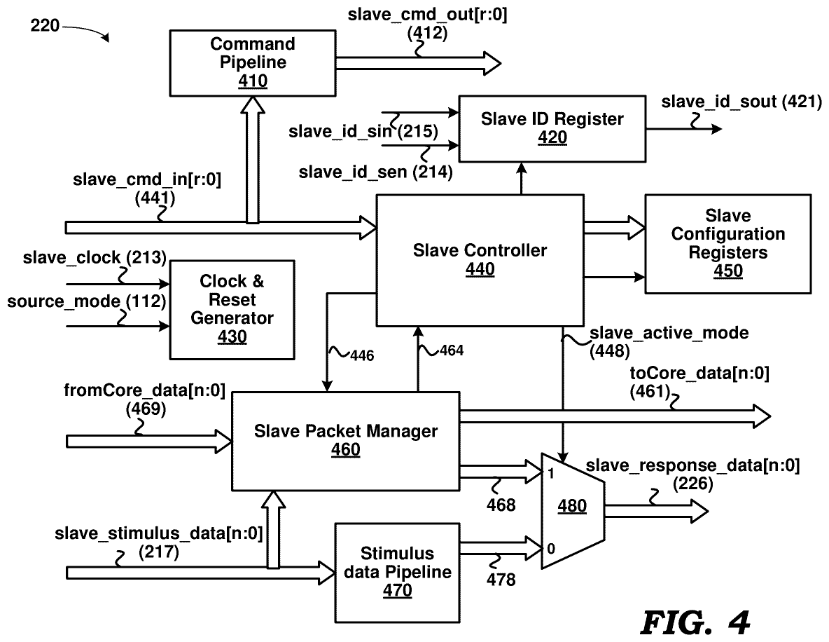

The descriptions of the signals between master 210 and slave 220 shown in FIG. 2 are provided in TABLE 2. The meaning of some of the signals in TABLE 2 will become clear from the description of FIG. 3 and FIG. 4 below.

TABLE 2

| Pin name | Direction | Width | Description |
|---|---|---|---|
| slave_clock (213) | output | 1 | Common clock for slave |
| | from | | units from master. |
| | Master | | |
| slave_id_sen (214) | output | 1 | Serial shift enable during |
| | from | | slave ID register |
| | Master | | programming phase. |
| slave_id_sin (215) | output | 1 | Serial input data to slave. |
| | from | | It is used for slave ID |
| | Master | | register programming. |
| slave_id_sout (221) | input to | 1 | Serial output data from |
| | Master | | slave. It is used for |
| | | | programming ID |
| | | | register of a slave |
| | | | further down the chain. |
| slave_cmd (212) | output | R | Command bus from |
| | from | | Master to Slave unit. |
| | Master | | This command bus |
| | | | synchronizes slave packet |
| | | | managers across the |
| | | | multiple slaves. The value |
| | | | of R is 2 to 3 based |
| | | | on features selected. |
| slave_stimulus_data | output | N | Stimulus data bus to slave |
| (215) | from | | unit. The minimum |
| | Master | | value of N is 8 and |
| | | | maximum value is 32. |
| slave_response_data | input to | N | Response data bus from |
| (226) | Master | | slave unit. The minimum |
| | | | value of N is 8 and |
| | | | maximum value is 32. |

Interface converter bridges (230) operate as an interface between a slave unit and a functional block. Bridges 230 converts signals (data, control signals, commands, etc.) conforming to the UTN protocol/specification (as described herein) received (on DOUT (223)) from slave 220 to those conforming to another protocol/specification that is used for transferring/applying (on path 235) test signals (e.g., commands, stimulus data) to the functional block. Bridges 230 also converts signals (e.g., response data) received on path 235 from the functional block according to the ‘another protocol’ to the UTN protocol, and forwards the converted signals to slave 220 on path DIN (238). Bridges (230) contains bridge-circuitry for such protocol conversions. The signals on paths DOUT and DIN are transferred synchronous with clock test_clock (224), which is generated by slave 220 and provided to bridges 230.

Four bridges are shown in FIG. 2—namely, IEEE 1149.1 TAP Interface (231), IEEE 1500 WTAP Interface (232), scan ATPG Interface (233) and Functional bus SPI (Serial Peripheral Interface)/I²S (Inter-Integrated Circuit Sound)/AHB (Advanced high-performance bus)/APB (Advanced Peripheral Bus) Bridges (234). Other bridges can be included for other types of tests. Bridges 230 can be implemented in a known way.

As an example, assuming that a scan-test is to be performed on the functional block, slave 220 forwards (or issues) test instructions and test data (together referred to as test signals) to ‘scan ATPG interface’ 233 for configuring the functional block for scan-test and running the scanning test on the functional block. Scan ATPG interface performs the protocol conversion from UTN to Scan ATPG, and sends the resulting signals to the functional block. Scan ATPG interface 233 performs the protocol conversion of the response data from the test back to UTN and forwards the converted response data to slave 220, which in turn sends the response to ATE 110 via master 210.

The internal implementation details of master 210 and slave 220 in an embodiment, are provided next with reference to FIG. 3 and FIG. 4 respectively.

### 5. Master Processor

FIG. 3 is a block diagram illustrating the details of a master processor in an embodiment of the present disclosure. Master processor (master) 210 is shown containing clock-and-reset-generator 310, master controller 320, master packet manager 330, M-to-N bits stimulus converter 230, stimulus data pipeline 350, multiplexer (MUX) 360, N-to-M bits response converter 370 and master setup registers 380. Each block is described below in further detail. It is noted here that although only one slave 220 is shown in FIG. 2, in general, there can be many slaves connected sequentially in a chain (or ring) as described in detail below. Hence, master 210 is noted generically below as issuing commands and forwarding data to the corresponding intended slave in the ring.

Clock-and-reset generator 310 receives source_clock (113) and source_mode (112) from ATE 110. When source_mode (112) is a logic 0, clock-and-reset generator 310 generates (asserts) reset signal (not shown) that resets all components of master 210. In response to source_mode (112) transitioning to logic 1, clock-and-reset generator 310 de-asserts the reset signal to enable operation of the components of the master for testing. Clock-and-reset generator 310 forwards (not shown in the Figure) source_clock (113) to the internal blocks in master 210 that operate based on source_clock (113). Clock-and-reset generator 310 buffers source_clock (113) and forwards a buffered clock named slave_clock (213) to slave 220. It is noted here that slave 220 would forward slave_clock (213) to its internal blocks and also to the next slave in the ring, as described further in sections below. All the clocked components in the master and slaves operate synchronously on a same clock (effectively, source_clock (113)). Clock-and-reset generator 310 forwards source_mode (112) (after buffering) to slave 220.

M-to-N bits stimulus converter 340 receives the M-bit instruction or data (generically referred to herein as packets) on bus 115, and converts the M-bit packet to N-bit packet, M being less than or equal to N. Converter 340 may contain one or more serial to parallel converters for such conversion. Converter 340 forwards the N-bit packets on internal bus (IBUS 343) to master packet manager 330 for storage and further processing.

Master controller 320 is the key block within master 210. Master controller 320 fetches instructions saved in master packet manager 330, decodes the instructions and performs tasks defined by the instructions. The tasks include issuing commands to the slaves and assigning IDs to slaves. Master controller 320 issues slave IDs (upon receipt of the same from ATE 110) on serial path slave_id_sin (215) and using ‘enable’ signal slave_id_sen (214). An example of slave ID assignment is illustrated in sections below. Master controller 320 issues commands to slaves on command bus slave_cmd (212). In conjunction with at least some commands, master controller 320 generates control and timing sequences for master packet manager 330 via path 323 to forward corresponding data to the corresponding slave on path slave_stimulus_data (217).

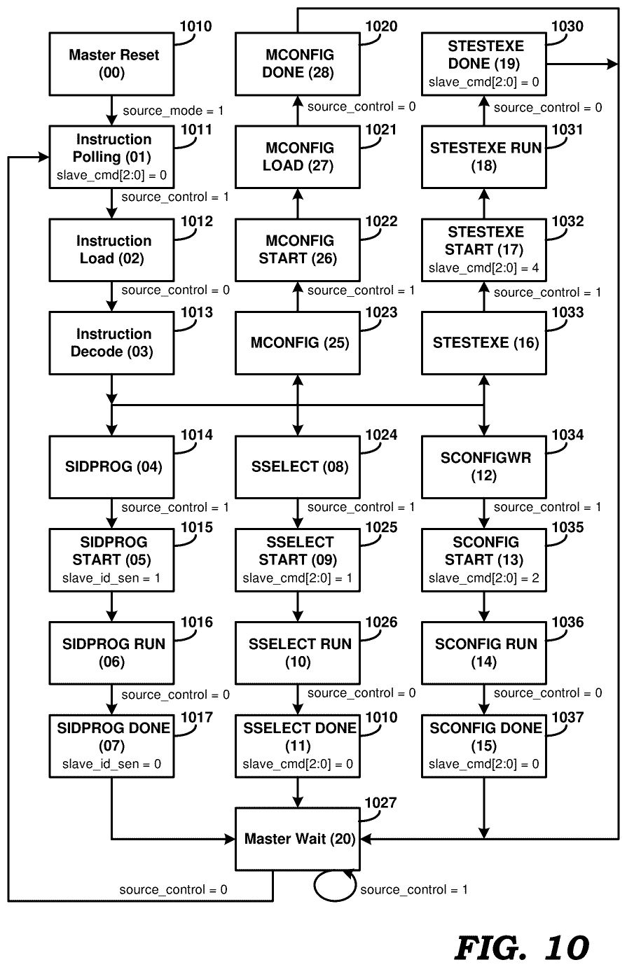

A finite state machine (FSM) implements master controller 320 (or the key portions of master controller 320). The FSM receives signal source_control (114). State transitions of the FSM are triggered by logic values of source_control (114). FIG. 10 is a state transition diagram 1000 showing some of the states and the corresponding state transition sequences of the FSM. In the interest of clarity and conciseness, only important states are shown and described below. However, the FSM has many more states, such as for example, enabling data-width scaling, frequency-scaling, enabling test, debug and ease of timing closure. The states shown in FIG. 10 are briefly described below.

In state transition diagram 100, each state is shown in a box (boxes are numbered 1010-1017, 1020-1027 and 1030-1037), and has a name and state code in parenthesis. Signal(s) generated by a state are also shown in the boxes. The signal and its corresponding value that causes transition from one state to another is indicated beside the arrow between the boxes representing the two states. In the example of FIG. 10, only one signal, namely command bus slave_cmd [2:0](212) is needed and the corresponding values are shown in the boxes when relevant. State (00) is a reset state, in which the FSM is held in reset with signal source_mode (112) being at logic 0. The FSM remains in the reset state as long as source_mode (112) is held at logic 0.

Transition of source_mode (112) to a logic 1 causes master 210 to be released from reset, and the FSM enters state (01), in which the FSM waits for an instruction to be received from ATE 110 on path 115. The FSM sets the value on command bus slave_cmd (212) to 0. Source_mode (112) must be maintained at logic 1 till the end of the testing session. A change to logic 0 of source_mode (112) at any stage of operation will reset the FSM, which would then return to the reset state.

The FSM enters state (02) upon source_control (114) changing to logic 1. In state (02), the FSM retrieves (loads) the instruction sent by ATE 110 on path 115 and which is saved in master packet manager 330 via block 340 and path 343.

The FSM enters state (03) upon source_control (114) changing to logic 1. In state (03), the FSM decodes the retrieved instruction, and transitions to the corresponding instruction execution branch depending on the instruction. In FIG. 10, only five instruction execution branches are shown. However, the FSM is designed to execute many more instructions.

Further, the FSM can be modified to include new instructions and corresponding execution branches in the future based on requirements.

Each instruction execution branch performs one task. Upon completion of the task, the FSM transitions to Master Wait (20) state, in which the FSM remains until source_control (114) changes to logic 0 from a logic 1.

Each of the five instruction execution branches (respectively shown starting at boxes 1014, 1020, 1024, 1030 and 1034) is described in detail with respect to an example below. The five instructions are respectively related to programming of slave IDs, configuration of master 210, selection of a slave, configuration of a slave and test execution on a slave.

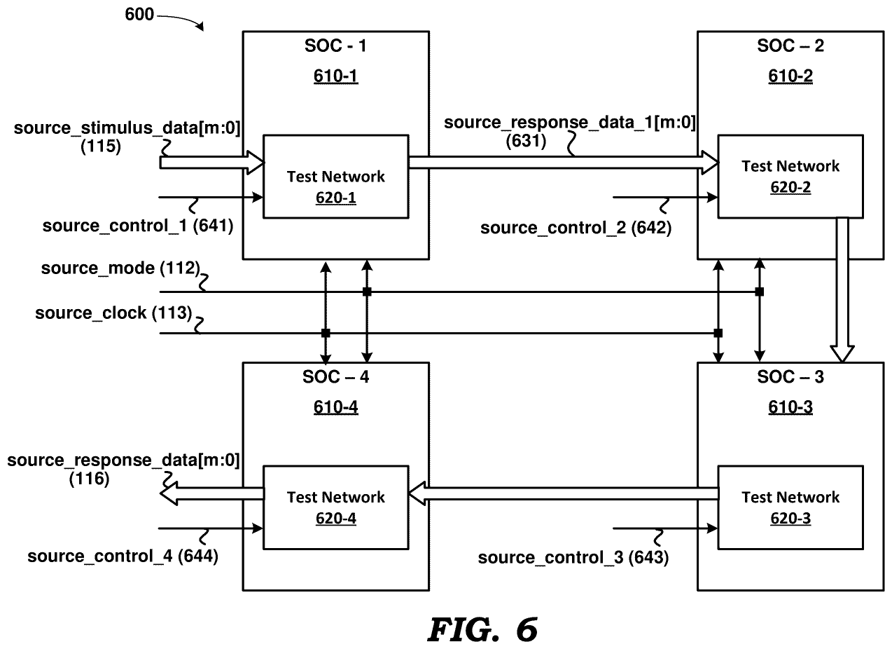

Continuing with reference to FIG. 3, when master 210 is active (operational), then master controller 320 generates a logic 1/high on path 326 (master_active_mode). When master 210 is bypassed and thus non-operational (i.e., configured to pass-through the packets to the next master as shown in FIG. 6), master controller 320 generates a logic 0/low signal on path 326.

Master Packet Manager 330 receives packets on bus 343 (IBUS), and via converter 340, from ATE 110 corresponding to the programmed packet size and slots allocated per packet by ATE 110. The packet size and slots-per-packet are based on several considerations, further described below and available in ATE 110, which configures master 210 with the corresponding values. Master packet manager 330 may internally queue the packets for retrieval by master controller 320, as noted above. Master packet manager 330 forwards those packets that are stimulus (test) data and slave configuration data on bus 215 to the corresponding slave selected beforehand using the slave's ID. The manner in which a slave is selected for receipt of data is illustrated in an example below. Master packet manger 330 forwards the packets under timing control from master controller 320.

Master packet manger 330 receives response data packets (response to tests executed on functional blocks) from slaves on slave_response_data bus (226) and forwards the response data packets to ATE 110 via path 336, MUX 360 and converter 370. MUX select signal 326 would be a logic 1/high when master 210 is active, causing MUX 360 to forward the response data on path 336 on its output and thus to converter 370. N-to-M bits response converter 370 re-packs the N-bit wide data to M-bit wide data and forwards the M-bit wide data on source_response_data bus 116 to ATE 110.

Master Setup Registers (380) represent a bank of registers that can be programmed to control set various parameters to be used during test operations, such as for example, data packet size, bandwidth allocation, test execution start time, test execution end time and clock frequency divisions. Some of such registers and the manner in which they are programmed are described in examples provided below.

Stimulus data pipeline 350 is operational only when Master 210 is in bypass mode during system-level test, i.e., when multiple SOCs constitute a system and the system is being tested. Such a system-level test set-up is described below. It is noted here that in a system-level test, the master processors of the respective SOCs forming the system are strung together in a ring fashion. A master of one SOC is bypassed, when ATE 110 transmits packets (instructions/data) intended for master/slaves of another SOC in the ring. Stimulus data pipeline 350 is a designed to perform a store-and-forward operation on each packet received from 340 that is intended for another SOC during a system-level test. In bypass mode, signal 326 would be a logic low and MUX 360 forwards a stored- and forwarded packet on input path 356 onto its output. Thus, in bypass mode, stimulus data pipeline 350 pipelines packets received via path 115 and converter 340, and forwards the packets on response data bus 116 via converter 370. Stimulus data pipeline 350 is included to ease timing closure and enabling high-speed operation.

The internal details of slave unit 220, in an embodiment, are provided and described next.

### 6. Slave Unit

FIG. 4 is a block diagram illustrating the implementation details of a slave unit in an embodiment of the present disclosure. Slave 220 is shown containing command pipeline 410, slave ID register 420, clock-and-reset generator 430, slave controller 440, slave configuration registers 450, slave packet manager 460, stimulus data pipeline 470 and MUX 480.

Clock-and-reset generator 430 receives slave_clock (213) and source_mode (112) from ATE 110. When source_mode (112) is a logic 0, clock-and-reset generator 430 generates (asserts) reset signal (not shown) that resets all components in slave 220. In response to source_mode (112) transitioning to logic 1, clock-and-reset generator 430 de-asserts the reset signal and enables operation of the components of the slave. Clock-and-reset generator 430, forwards slave_clock (213) to the various clocked components of slave 220, which operate in synchronism with the forwarded clock. Clock source_clock (113), internal clocks in the master and the clocks in the slave units in a system or SOC are all synchronous with respect to each other, and also of the same frequency.

Slave Controller 440 receives commands on command bus slave_cmd_in[r:0](441) from master 210. For slave 220, slave_cmd_in[r:0](441) corresponds to slave_cmd[r:0](212) of FIG. 3, since slave 220 is directly connected to (next/proximal to) master 210, as shown in FIG. 2. For the other slave units, slave_cmd_in[r:0](441) would correspond to slave_cmd_out[r:0](412) of the immediately previous slave in the ring. Slave 220 executes the received commands by programming various registers in slave configuration registers (450) such as test-start register, test-stop register, packet-size register and packet-slot-allocation-index registers, etc., described below.

Slave controller 440, in conjunction with commands received on slave_cmd_in (441), sends control signals to slave ID Register 420 for shifting-in (and storing) its own slave ID received via master 210 on path slave_id_sin (215), as well as for causing a slave ID received on path 215 that is intended for another slave downstream in the ring to pass (feed-through or shifted-through) through slave ID register 420 to the next slave on path slave_id_sout(421).

Slave_id_sen (214) is an enable signal that enables programming of slave IDs. Programming of slave IDs is illustrated in an example below. Slave controller 440 generates control signals on path 446 needed for the operation of slave packet manager 460.

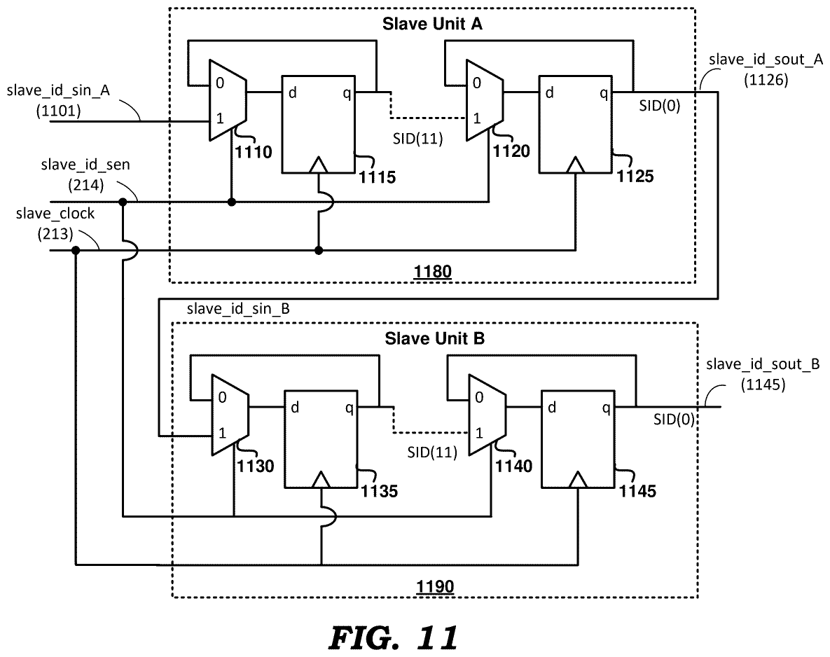

Slave ID register 420 is a 12-bit register (in an embodiment) that stores the slave unit ID assigned (and received on path 215, with enable-signal 214 being asserted) by master controller 320 of master 210. FIG. 11 is a diagram illustrating the internal details of slave ID register as well as the way the slave ID registers of multiple slaves are connected in a sequential (and ring) fashion in an embodiment. Slave ID registers 1180 and 1190 of two adjacent slaves (slave unit A and slave unit B) are shown there. For illustration, register 1180 is assumed to be contained in slave 220 (slave unit A) and register 1190 in that of the immediately next slave (slave unit B) in the ring. Each bit storage of slave ID register is made of a flip-flop (FF) and a multiplexer (MUX).

MUX 1110 and FF 1115 correspond to the most significant bit (MSB) (SID 11) of slave ID register 1180 and MUX 1120 and FF 1125 to the least significant bit (LSB) (SID 00) of slave ID register 1180. MUX 1130 and FF 1135, and MUX 1140 and FF 1145 correspond respectively to the MSB (SID 11) and the LSB (SID 00) of slave ID register 1190. The intervening set of FF and MUXes of each register are not shown, but implied by the dashed line above SID (11) of each register, and are implemented similar to a set of MUX and FF shown in FIG. 11. The slave ID register of each of the other slaves (when present) is also implemented similar to registers 1180 and 1190 shown in FIG. 11. The slave ID registers are connected sequentially in a ring fashion, with the output of a register feeding the input of the next register. The serial output slave_id_sout of the last slave in the ring is connected to the input slave_id_sout (221) of master 210, as shown in FIG. 3.

MUX 1110 is connected to path slave_id_sin_A (1101), which for slave 220 corresponds to path 215 of FIG. 4. The output of MUX 1110 is connected to the data (D) input of FF 1115. The other input of MUX 1110 is connected to the Q (Q) output of FF 1115 as well as the next MUX (not shown). The other MUXes and FFs of FIG. 11 are connected similarly. Q output of FF 1125 is connected to path slave_id_sout_A (1126), which for slave 220 corresponds to path 421 of FIG. 4. The serial input of register 1190 is the serial output slave_id_sout_A (1126) of register 1180. The serial output slave_id_sout_B (1146) of register 1190 would be connected to the serial input of the next register in the ring. All the FFs of the slave ID registers receive slave_clock (213) on their respective clock inputs. Enable signal slave_id_sen (214) is connected to the ‘select’ input of the MUXes of the slave ID registers. Signals slave_clock (213) and slave_id_sen (214) are broadcast to all the slaves by master processor.

When slave_id_sen (214) is driven to logic value 1, all the slave ID register FFs are configured as a shift register, and master 210 programs the slave ID of each slave unit in a single-pass shift operation. Such shift operations to program the slave ID registers of slaves is illustrated in an example below with a timing diagram. Once the slave IDs have been correctly programmed into the corresponding ID registers, slave_id_sen (214) is driven to logic value 0, and each slave register ID thereafter holds respective the programmed IDs.

In an embodiment, there is no hard-coded slave ID. Instead, the slave ID is dynamically generated in ATE 110 during SOC-level pattern generation process, as described in sections below. The use of dynamic slave IDs alleviates the need for hard coding IDs at the time of design.

Slave configuration registers 450 contains a bank of registers that are programmed by slave controller 440 (with data values received from ATE 110 and via master 210) to set data packet size, bandwidth allocation, test execution start time, test execution end time and selection of desired bridge interface. Selection of desired bridge interface refers to enabling the specific one of the multiple interfaces in a slave, such as interface bridges 231, 232, 233 and 234 shown in FIG. 2. The selected interface would be that through which a test is desired to be performed on the corresponding functional block. The purpose of these registers is clarified below with examples.

Slave packet manager 460 receives packets on slave_stimulus_data bus (215), the packets conforming to the programmed packet size and allocated slots per packet. Slave packet manager 460 forwards packets intended for slave 220 via bus toCore_data (461) (which corresponds to DOUT 223 in FIG. 2) to the selected interface (in bridges 230 of FIG. 2) and as indicated by slave controller 440 on path 446. The selected bridge interface is the one corresponding to the test to be performed next on the functional block. Slave packet manager 460 receives response data on bus fromCore_data (469) (which corresponds to DIN 238 of FIG. 2) from the selected bridge interface (via which a test has just been completed), generates corresponding response packets and forwards the packets on slave_response_data bus (226) via path 468 and MUX 480. The ‘select’ input to MUX 480 is provided as a logic high by slave controller 440 on path slave_active_mode (448).

When slave 220 is set in bypass mode (to allow slave 220 to forward packets received from master 210 that are intended for other slave(s) in the ring), stimulus-data pipeline 470 pipelines (by latching) the stimulus data received on bus 215, and forwards the data on slave_response_data bus (226) via MUX 480. In slave-bypass mode, signal slave_active_mode (448) is a logic 0, and MUX 480 forwards the data on path 478 to path 226. This pipeline eases timing closure and enables high speed operation of the UTN data bus. It is noted that, for the other slaves in the SOC, the slave_stimulus_data bus would be connected to the slave_response_data bus of the immediately previous slave in the ring, while the slave_response_data bus would be connected to the immediately next slave's slave_stimulus_data bus.

Command pipeline 410 pipelines (by latching) commands received on slave_cmd_in bus (441), but which are meant for a different slave unit in the ring, and forwards the commands to the next slave unit on slave_cmd_out bus (412). Command pipeline 410 provides synchronous feedthrough for slave command bus for easy timing closure.

A slave is operable in one of multiple modes. In an embodiment, a slave is operable in one of three modes. Operating mode can be programmed using a slave's mode_sel [1:0] control bits. These control bits correspond to bits 0 and 1 of slave_config_control register of the slave. Slave_config_control register is contained in slave configuration registers 450.

Table 3 below lists the control bit values needed for each mode:

TABLE 3

| slave_mode_sel[1] | slave_mode_sel[0] | Mode name |
|---|---|---|
| 0 | X (don't care) | Bypass mode |
| 1 | 0 | Packet Flowing mode |
| 1 | 1 | Packet Frozen mode |

The three modes are now described.

Slave Bypass Mode: In this mode, the slave does not participate in packet processing activity. The slave_stimulus_data input bus (bus 215 in FIG. 4) of the slave is routed directly to the slave_response_data output bus (bus 226 in FIG. 4) of the slave (but via stimulus data pipeline—e.g., 470 of FIG. 4). In slave bypass mode, slave remains completely inactive functionally. The default reset mode of all the slave units is the ‘slave bypass mode’. The bypass mode ensures slave ring (data flow path) is not broken even when the slave is completely inactive.

Packet-Flowing Mode: In this mode, the slave samples (i.e., reads and responds to) data words in the packets received on slave_stimulus_data bus (bus 215 in FIG. 4), the data words being contained in slots assigned to the slave. The slave also inserts, in response packets (of the response packet stream), response words in slots assigned to the slave. The selected bridge gets continuous flow of data words from the data packet stream. This mode is used in tests that require different data in every stimulus word and/or every response word needs to be strobed on the ATE. For example, ATPG tests fall under this category. The slave unit in the packet flowing mode performs two tasks. The first task is to receive stimulus data from the stimulus bus and send response data to the response bus, which represents a ‘packet processing task’. The second task is to keep the corresponding bridge operation running by supplying proper clocks, data and resets to the bridge, which represents a ‘bridge operation task’. In summary, in the packet flowing mode the slave unit is fully operational and performs both the tasks.

Packet-Frozen Mode: In this mode, the slave does not sample data words in the packets received on slave_stimulus_data bus, nor does it insert response words in the response packet stream. Instead, the slave continues to (sometimes repeatedly) apply the last packet it received when it was in the packet-flowing mode prior to entering into the packet frozen mode. The slave unit also ignores all response words received from the functional block. Thus, in this mode, the slave does not use the slave_stimulus and slave_response data buses. This mode of operation allows packet slots assigned to a slave in the packet-frozen mode to be used by another slave set to operate in packet-flowing mode. It is not necessary for a slave unit in the packet-flowing mode to be a neighbor of a slave in packet-frozen mode. The only requirement is that both must be assigned the same slot index in the packet. At the same time, this mode keeps the selected bridge and its operation active. This mode is ideal for tests such as Built-In Self-Test (BIST). For example, memory BIST and logic BIST tests do not need input stimulus data once the BIST engine is started. This feature reduces UTN packet transmission bandwidth requirements by eliminating transmission of the same stimulus word(s) repeatedly for a large number of clock cycles. In summary, in the packet-frozen mode, a slave unit is partially operational as it stops performing packet processing task but continues to perform bridge operation task.

All the other slaves in SOC 120 are implemented similar to slave 220 as described above.

The operations of a master and a single slave (the slave immediately next to the master in the ring) have been described above. As noted above, an SOC typically contains multiple functional blocks, with each block performing a corresponding function/operation. Each block is typically tested independently for functionality, structural faults, etc. The UTN architecture, therefore, provides one slave unit per functional block. The inter-connection of a master and multiple slaves of an SOC as well as packet flow in such multi-slave environment are described next.

### 7. SOC Having Multiple Slave Units

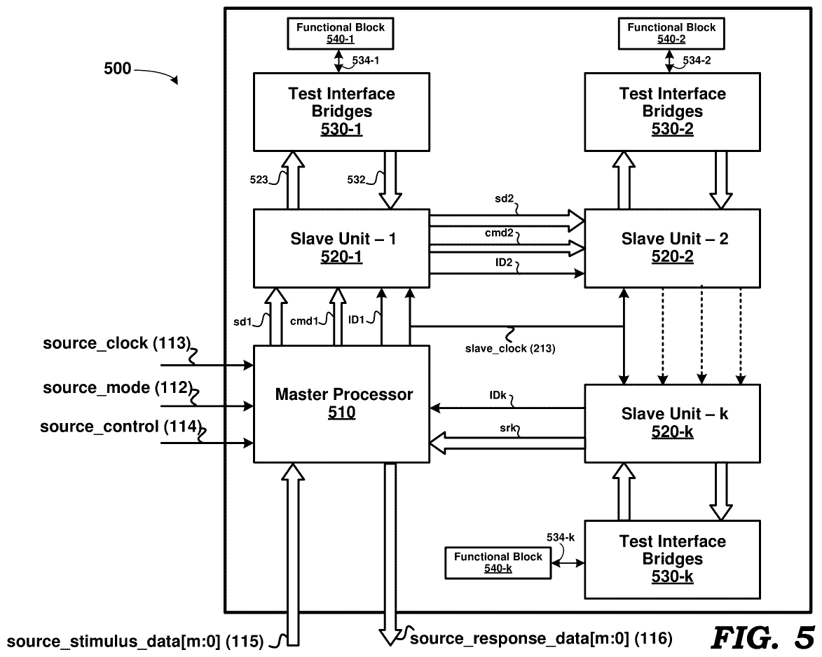

FIG. 5 is a block diagram illustrating a SOC with multiple slave units in an embodiment. SOC 500 has multiple functional blocks (not shown). Each functional block is directly connected to a corresponding slave unit, and thus there is only a single slave unit per functional block. SOC 500 of FIG. 5 is shown containing master processor (master) 510, slave units (slaves) 1 through k (520-1 through 520-k), test interface bridges (bridges) 1 through k (530-1 through 530-k), and functional blocks 540-1 through 540-k.

Master 510 and the slave units are connected in an ordered daisy-chain fashion, and together form a ‘slave ring’. The ‘slave ring’ starts at master 210 and traverses through all the slave units and ends at master 510. A slave ring represents the physical connectivity topology among a master and its slave units in an SOC. Slave 520-1 is referred to as the head slave since it is the first slave in the slave ring. Slave 520-k is referred to as the tail slave since it is the last slave in the slave ring.

Master 510 is similar or identical to master 210 of FIG. 2, and the description is not repeated here in the interest of conciseness. Paths 112, 113, 114, 115 and 116 are shown here connected to master 510, and correspond to the similarly-numbered paths of FIGS. 1 and 2.

Each of slaves 520-1 through 520-k (i.e., k slaves, wherein k is an integer greater than 1) is implemented identical to slave 220 of FIG. 2, and the details are not repeated here in the interest of conciseness. Slaves 520-1 through 520-k are connected sequentially, i.e., slave 520-1 is connected directly to master 510, slave 520-2 is connected to slave 520-3 and so on, with slave 520-k being connected to master 510. The master and slaves are thus connected in a ring (chain) fashion, noted above as a ‘slave ring’.

Each slave receives a clock, a mode signal, a command input, stimulus data, slave ID input, and slave ID enable input as inputs on corresponding input paths. The clock signal is common to all the slaves in an SOC, and corresponds to slave_clock (213) of FIG. 2, which is shown being connected from master 510 to all the slaves in FIG. 5. Master 510 broadcasts slave_clock (213) to all slave units in SOC 500. The mode signal is not shown in FIG. 5, but corresponds to source_mode (112).

Master 510 generates commands (based on inputs/instructions from ATE 110) for each of the slaves in SOC 500 on a command bus cmd_bus (similar to bus 212 of FIG. 3). The command bus from master 510 to the input of the first slave in the ring, namely slave unit 520-1, is shown connected to the output labelled ‘cmd1’ of master 510 in FIG. 5. Label ‘cmd1’ corresponds to slave_cmd [r:0](212) of FIG. 3. The command bus (212) feeds-through each slave. Thus, slaves that are earlier in the ring forward commands destined for slaves further down in the ring on their respective slave_cmd_out output bus (such as 412 in FIG. 4).

Thus, for example, a command from master 510 to slave 520-k would be provided by master 510 on cmd1. Slave 520-1 would forward the command on path cmd2 (which corresponds to path 412 in FIG. 4) to slave 520-2. The other slaves forward the command until it reaches slave 520-k.

Stimulus data and slave ID from master 510 to a slave move through the ring similarly as commands as noted above. The stimulus data input bus of a slave is directly connected to the response data output bus of the immediately previous slave in the ring, except for slave 520-1, which has its stimulus data input bus connected to the stimulus data output bus of master 510. The stimulus response output bus of slave 520-k is connected to the slave response data input bus of master 510. In FIG. 5, The stimulus data input paths to slave 520-1 and 520-2 are noted respectively as sd1 and sd2. sd1 corresponds to bus slave_stimulus_data (217) in FIG. 4. sd2 would correspond to the slave_stimulus_data input of slave 520-2, which would be connected to slave_response_data[n:0](226) of slave 520-1.

As described above, slave IDs transmitted by master 510 travel through the corresponding slaves' slave_id_sin input, slave ID register and slave_id_sout output until the destination slave is reached. The slave_id_sin input of a slave (except slave 520-1) is connected to the slave_id_sout of the immediately previous slave. The slave_id_sin of slave 520-1 is connected directly to output 215 of master 510. Slave ID input paths ID1 and ID2 respectively of slaves 5201- and 520-2 are marked in FIG. 5. ID1 corresponds to slave_id_sout (215) in FIG. 4, and ID2 corresponds to slave_id_sout (421) of slave 520-1.

Response data from a slave similarly moves through the slaves further down until the response data reach master 510. Response data from a slave is provided on the slave's slave_response_data output bus, which is connected to the slave_stimulus_data input bus of the immediately next slave in the ring. The slave_response_data output bus of slave 520-k is directly connected to slave_response_data input bus of master 510.

Packets, commands and slave IDs from the master to the slaves in a slave ring may be viewed as ‘flowing through, or on, the daisy-chain’ formed by the sequential connection of the master and slave in the slave ring.

Each of slaves 520-1 through 520-k is shown connected to a corresponding set of test interface bridges 530-1 through 530-k respectively, which are in turn shown connected to respective functional blocks 540-1 through 540-k via paths 534-1, through 534-k. As also noted above with respect to bridges 230 of FIG. 2, bridges in each of 530-1 through 530-k convert/map the data/command/control signals received from the corresponding slave to the corresponding interface. Each of bridges 530-1 through 530-k includes the bridges needed for IEEE 1149.1, IEEE 1500, MBIST, scan ATPG chains and clocks, functional buses such as APB, AHB, SPI, I²S. Each slave provides stimulus data, instructions and control signals (needed for testing the corresponding functional block) to the corresponding functional block via the corresponding test interface bridge, and receives response data (generated by the test) from the functional block via the corresponding bridges. Thus, in FIG. 5, slave 520-1 is shown providing the above-noted inputs to bridges 530-1 on paths 523, and receives response data on paths 532.

It may be observed from the description herein that UTN provides a single high-speed data network from an SOC's pins (to which an ATE may be connected) to every functional block. For each functional block, a corresponding set of interface bridges provide and drive the required test and functional interfaces independently from interface bridges connected to another functional block. As a result, tests can be performed concurrently in multiple functional blocks.

Each slave has a dedicated pin/port for receiving signal source_mode (112) from master 510. The other pins/ports of a slave can be shared for multiple types of information/signal/packets. For example, both stimulus data and response data can travel through the same bus the ring, as noted above. The flow of some signals and packets in a daisy-chain fashion as described above helps to reduce routing congestion on the SOC as well as allowing for synchronous pipelining of high-speed buses. The daisy-chained structure breaks down a long timing paths into smaller timing paths by inserting flip-flops (known as pipeline flip-flops) in each slave unit along the long timing path. To illustrate, stimulus-data pipeline 470 shown in FIG. 4 is implemented to contain a flip-flop in the path from input bus 215 to output bus 226 (via path 478 and MUX 480). The shorter timing paths allow higher speed of data-transfer. In an embodiment of the present disclosure, and as noted above, the shared (also termed feedthrough) ports are slave_stimulus_data[n:0], slave_cmd_bus[r:0], slave_id_sin and slave_id_sout. There is no limit on the number of slave units that can be connected in a daisy-chain fashion in an SOC.

A system may contain multiple SOCs. The UTN architecture is designed to accommodate testing of multiple SOCs of a system in a single framework, as described next.

### 8. System Having Multiple SOCs

FIG. 6 is a block diagram illustrating the manner in which the UTN components of multiple SOCs of a system are connected for testing. In FIG. 6, a system having four SOCs, namely 610-1 through 610-4 is shown. SOCs 610-1 through 610-4 (combinedly referred by numeral 610) are shown containing on-chip UTN (test network) components 620-1 through 620-4 (combinedly referred by numeral 620), each of which would be similar to the set of components of SOC 500 of FIG. 5. An ATE (e.g., ATE 110) would be directly connected to the corresponding input pins/ports of UTN 620-1 and the corresponding output pins/ports of UTN 610-4. UTN 620-1 is the first slave in the chain/ring, and UTN 620-4 is the last.

The master processors (masters) contained in test networks 620-1 through 620-4 and the ATE are connected in an ordered daisy-chain fashion, and form a ‘master ring’. In the master ring, only the master processors are included. Slave units are not included in the master ring. In the master ring, the master in test network 620-1, i.e., the very first master in the ring, is referred to as the head master. The master in test network 620-4, i.e., the last master in the ring, is referred to as the tail master.

UTN component 620-1 would contain one master and multiple slaves, with the master and slaves connected as depicted in FIG. 5, with the exception that the outputs of the master in component 620-1 would be connected to the corresponding inputs of the master in component 620-2. Similarly, UTN component 620-2 would contain one master and multiple slaves, with the master and slaves connected as depicted in FIG. 5, with the exception that the outputs of the master in component 620-2 would be connected to the corresponding inputs of the master in component 620-3, and so on.

Each component 620-1 through 620-4 requires and receives a unique control signal akin to source_control (114) of FIG. 1. Thus, in FIG. 6, the respective UTN components are shown receiving control signals source_control_1 (641), source_control_2 (642), source_control_3 (643) and source_control_4 (644), each of which is generated by an ATE (such as ATE 110). Mode and clock signals from the ATE are common to all the SOCs. Thus, mode signal source_mode (112) and clock source_clock (113) are shown provided/broadcast as inputs to all four UTN components (620).

Within each UTN component 620, the stimulus/data buses to/from each slave would be connected in a daisy-chain as in FIG. 5, except that the response data bus from the master would be connected to the stimulus data bus of the next master in the master ring. To illustrate, bus source_stimulus_data (115) connects the stimulus data bus output of the ATE to the stimulus data input bus of the master in SOC 610-1. The source_response_data_1 bus (631) from the master in SOC 610-1 connects the response data outputbus of the master in SOC 610-1 to the stimulus data input bus of the master in SOC 610-2. The stimulus and response buses of the other masters are connected similarly. The response data output bus of the last master in the master ring (namely master of SOC 610-4 and component 620-4) is connected to the response data input bus source_response_data (116) of the ATE.

The daisy-chaining technique minimizes the number of pins needed on each SOC as well as in the ATE needed for testing. The technique also simplifies connections needed for testing multiple dies packaged using 2.5D and 3D packaging.

It may be appreciated from the foregoing description that the Universal Test Network (UTN) provided according to an aspect of the present disclosure provides a single high-speed gateway for SOC-testing at system level, package level, SOC level and block level. UTN supports both structural and functional testing. Also, UTN enables concurrent application of multiple structural tests, multiple functional tests and combinations of structural tests and functional tests. Such concurrent testing ability results in significant test-cost savings.

The structure of packets used in a UTN and allocation of slots for different tests are described next.

### 9. UTN Packets and Bandwidth Management

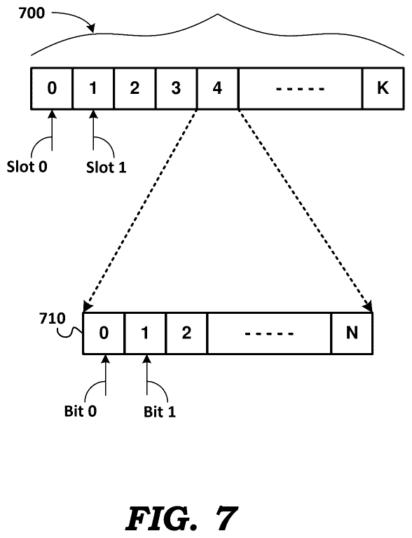

FIG. 7 is a diagram illustrating the details of a packet as used in a UTN in an embodiment of the present disclosure. Packet 700 packet is divided into ‘K’ slots (slot 0 and slot 1 are indicated in FIG. 7). Each slot has a duration of one ‘time division’, which is equal to the period of the UTN system clock (e.g., source_clock (113) in FIG. 1) generated by the ATE. Each slot is assigned a unique index number starting from the left-most slot, i.e., the earliest slot in time in the packet. Thus, the left-most slot (slot 0) is shown assigned the index 0, and the index number increases by 1 every slot towards the right of the packet. In an embodiment, the number of slots per packet can range from 1 to 255.

Each slot of packet 700 contains N bits, N being an integer (typically a power of 2), and the N bits together constitute one “word” of data. Thus, slot 4 of packet 700 is shown containing bits 0 through N. One word of data contains the number of bits (here N) that are transferred or processed in one clock cycle (of the system clock) by the Master processor. In an embodiment, the word size is equal to the width of the slave stimulus data bus (e.g., bus 215 in FIG. 2). In the embodiment, the width of the slave stimulus data bus is equal to the width of the slave response data bus (e.g., bus 226 in FIG. 2). A group of contiguous bits in a word is referred to herein as a ‘slice’. The size/width of a slice can range from 1 to N bits.

An example scenario illustrating the packets transmitted by an ATE for testing five functional blocks in an embodiment is described next.

In the example (example 1), a SOC has five functional blocks named A, B, C, D and E respectively. The number of system clock cycles needed to completely test each block is assumed as follows:

$$Block A - test length La = 100 cycles$$

$$Block B - test length Lb = 80 cycles$$

$$Block C - test length Lc = 50 cycles$$

$$Block D - test length Ld = 40 cycles$$

$$Block E - test length Le = 20 cycles$$

Figure is a diagram illustrating the data packets generated by the UTN software (described below) and applied by the ATE for completely testing all of the five blocks. The total number of packets needed equals the length of the longest test, which is 100 cycles (for Block A) in the example. The number of slots per packet is 5, one for each of the 5 blocks A through E. Each slot is assumed to contain one stimulus data for the corresponding block. Therefore, the total number of cycles (of the system clock) needed equals the product of the longest test length (here 100) and the number of slots per packet (here 5), i.e., 500.

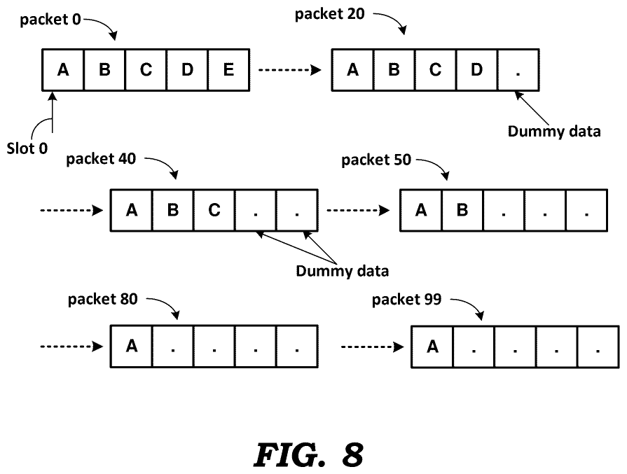

In FIG. 8, packet 0 is the first packet and packet 99 is the last. Packet 0 is shown containing five slots—one each for functional blocks A, B, C, D and E. Slot 0 of packet 0 contains the (first) stimulus data for block A, slot 1 of packet 0 contains the (first) stimulus data for block B, and so on. Packets 0 through 19 would each contain one stimulus data for each of the five blocks. Testing of Block E would be complete with packet 19. Packet 20 is shown containing data only for blocks A, B, C and D. The slot (slot 5) corresponding to block E in packet 20 contains undefined/dummy data. Slots with dummy data are indicated in FIG. 8 by a ‘.’. In a similar manner, testing of Block D would be complete with packet 390, and packet 40 is shown containing data only for blocks A, B and C. Packets 50, 80 and 99 are also shown in the Figure.

It may be observed that the above-noted technique of packet formation and slot allocation may be inefficient if the test length (number of stimulus words needed) of the blocks are substantially different, since many slots are unused and filled with dummy padding words. The technique requires larger memory storage space and consumes longer test times.

An alternative technique of packet formation that employs slot-sharing is used in another embodiment of the present disclosure, and is described next.

### 10.1 Packet Slot-Sharing Technique

In an alternative embodiment, functional blocks to be tested are grouped such that the average test length of all the groups is substantially equal. Continuing with the scenario in example 1 above, in the alternative embodiment, three groups X, Y and Z are defined as follows:
Group X: Block A. Test cycles of the group Lx=La=100
Group Y: Blocks B and E. Test cycles of the group Ly=Lb+Le=80+20=100
Group Z: Blocks C and D. Test cycles of the group Lz=Lc+Ld=50+40=90

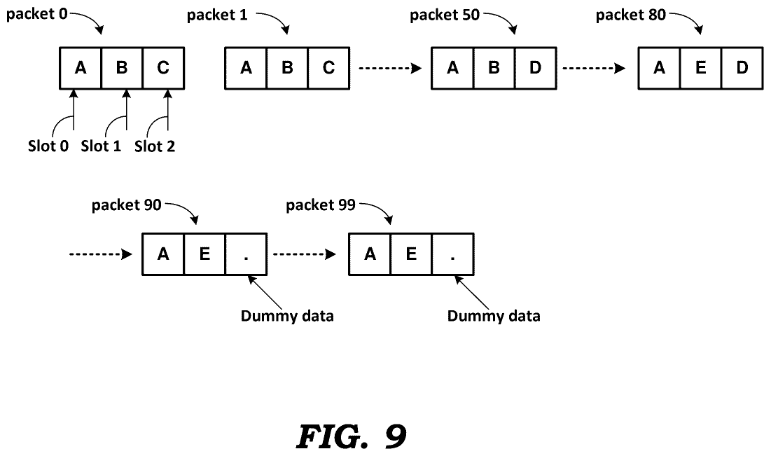

It may be seen that groups X, Y and Z are almost equal in terms of the number of test cycles required. The number of packets required to complete all the tests is equal to the longest group test length 100. The packet slot assignment is shown in FIG. 9. The number of slots in each packet is set to be the number of groups, 3 in this example. In the example, slot 0 of the packets is assigned to group X, slot 1 to group Y and slot 2 to group Z.

Packets 0, 1, 50, 80, 90 and 99 are shown in FIG. 9. In group Z (slot 2), tests for block C finishes with the 50^{th} packet (packet number 49, not shown). Hence, from packet number 50 onwards, slot 2 is assigned to tests for block D until tests for block D are complete. In a similar manner, tests for block B finishes with the 80^{th} packet (packet number 79, not shown), and tests for block B are assigned slot 1 thereafter. The total number of system clock cycles needed to complete all tests is 300, which is 40% less than the 500 cycles that were needed in the technique of FIG. 8. The slot-sharing technique of FIG. 9 therefore needs lesser test memory storage and reduces test time. This scheme can be implemented by programming test start and test stop cycle counters of each slave unit.

In yet another embodiment of the present disclosure, the technique of packet formation employs slots proportional to the length of the test, as described next.

### 10.2 Assigning Slots Proportional to Test Length

In this technique slots per packet are assigned based on ratios of the test lengths. Continuing with the scenario of example 1 above, the ratio of the test lengths is as follows:

$$test length ratio = La : Lb : Lc : Ld : Le = 100 : 80 : 50 : 40 : 20$$

Dividing the test lengths by 20 and rounding off the next higher integer, the ratios are expressed as 5:4:3:2:1. In the technique the number of slots per packet assigned for tests of the five blocks are as follow:
5 slots for test A, 4 slots for test B, 3 slots for test C, 2 slots for test D and 1 slot for test E.
Therefore, total number of slots per packet=5+4+3+2+1=15
Total number of packets required to complete all tests is 20 (the divisor used to get the ratio)

Total system cycles needed=Total packets*number of slots in a packet=20*15=300.

It can be observed that the total number of system clock cycles needed to complete all tests is 300, which is 40% less than the 500 cycles that were needed in the technique of FIG. 8, and thereby reducing storage memory and test time requirements. This technique can be implemented by programming the slot-start and slot-stop index counters of each slave unit.

### 10.3 Word-sharing Technique

In this technique, slices of a word are allocated to multiple tests. Each word still fits in one slot. The sum of the bits of the multiple slices within a word must be equal to or less than width of the word. This technique can be used on top of either technique described in sections 10.1 or 10.2 to further reduce storage memory and test time. This technique is particularly useful when some tests need fewer bits than the word length.

### 10.4 Frozen Packet Technique

The packet-frozen mode of operation of a slave, described above, facilitates the re-assignment of slots assigned to that slave to another slave. Slave units that are executing Built-In Self-Tests (BIST) like Memory BIST, Logic BIST, Functional BIST or Analog BIST do not need continuous access to stimulus data bus and response data bus. A slave unit uses the IEEE 1500 WTAP interface (232 in FIG. 2) for BISTs. Once the test is setup and started, the IEEE 1500 bridge (e.g., 232 of FIG. 2) remains in an idle state till the BIST execution completes. During BIST execution phase slots allocated to the host slave (the slave on which the BIST is being performed) are unused. This results in significant wastage of UTN packet bandwidth. The feature of Frozen Packet technique eliminates this wastage of UTN packet bandwidth.

In Frozen Packet Technique, a slave that needs, for example, to run a BIST is reprogrammed into the packet-frozen mode after starting the BIST. In packet-frozen mode, the slave does not consume packet slots but continues to repeatedly apply the last packet data it received in the packet-flowing mode just prior to entering the packet-frozen mode. Also, the slave unit does not disturb the operation of the bridge executing the BIST. The slots assigned to the slave unit that has been programmed to be in in Packet-Frozen mode can be re-assigned to other slave units that need to run tests that require continuous flow of data (such as scan ATPG tests or functional tests) to and from the ATE. Once BIST execution completes, the slave unit can be reprogrammed into Packet Flowing mode so that the ATE can collect PASS/FAIL status or BIST diagnostic data.

### 11. Synchronization of Packet Counters and Slot Counters Across Slave Units

The master processor and all the slave units have built-in packet counters and slot counters. A packet counter in a slave/master keeps track of the number of data packets sent by the ATE on bus source_stimulus_data (e.g., 115 in FIG. 1). Similarly, a slot counter keeps track of the current slot count. For proper operation of the UTN, robust and stable synchronization needs to be ensured among all the slave units. More specifically, packet managers (such as 460 of FIG. 4) of all the slave units of an SOC must be synchronized.

Synchronization is achieved by maintaining equal number pipeline stages between slave command bus (e.g., 441 of FIG. 4) and slave stimulus data bus (e.g., 215) connected to each slave unit. Each slave unit introduces two pipeline stages (with one flip-flop in the corresponding path creating one stage of pipeline), in the path of the slave command bus and slave stimulus/response data bus. Thus, in each slave, in the path of the command bus, command pipeline block (410 of FIG. 4) contains two stages of flip-flops and performs one instance of storage of the input command. In the path of the stimulus data bus, stimulus data pipeline (470 of FIG. 4) contains two stages of flip-flops and performs one stage of storage of the corresponding input packet.

Synchronization is achieved using the following operations in sequence:
I. Master receives test execution instruction.
II. Master activates ‘slave sync trigger’ command on slave command bus.
III. Two cycles later, master starts sending data packets over slave stimulus data bus.
IV. Each slave packet manager de-asserts reset of local packet counter and slot counter.
V. When the local packet counter reaches the pre-configured test-start count value, the slave unit starts data packet processing (extraction and insertion of slots) from slave stimulus data bus.
VI. Similarly, when local packet counter reaches the pre-configured test-stop count value, the slave unit stops data packet processing.
VII. Once the slave unit's packet counter reaches stop count, the slave enters test execution wait state and stays there till the end of current test execution instruction.
VIII. After the slave unit stops packet processing, its slot can be assigned to some other slave unit.

Example operations of the components of the UTN from initialization to testing are described next with examples.

### 14. Operation of the UTN

The operations of the UTN are divided into four phases. An SOC can be in the functional mode (the SOC is operating to provide the functions it is designed for) or in the test mode (the SOC is being tested or initialized for test. In the functional mode (also known as mission or normal mode), signal source_mode is set to 0, which holds the UTN in a reset state and therefore inactive. Other UTN pins such as source_clock, source_control, source_stimulus_data and source_response_data can be multiplexed with normal/mission functions in functional mode. In test mode, signal source_mode is set to 1. In summary, UTN needs only one additional dedicated input pin/port namely, signal source_mode. All other UTN inputs and outputs can be shared (i.e., multiplexed) with other functional inputs and outputs (the signals that are used by the SOC in normal/mission operation).

An example test, and the steps of the 4 phases specifically adapted/related for the test are described next.

### 14.1 Example Tests and Corresponding Steps of the 4 Phases

In the example below, a SOC with two functional blocks, namely block_A and block_B, is considered. The SOC has a UTN master and two slave units—slave_A for block_A and slave_B for block_B. A memory test (mbist_test_A) is to be performed on block_A, and a Scan ATPG test (scan_test-B) is to be performed on block_B. Memory test on block_A is run using IEEE 1500 WTAP interface, i.e., using WTAP bridge (e.g., 232 of FIG. 2) connected to slave_A. The Scan ATPG test is run using scan bus interface, i.e., scan bridge (such as 233 of FIG. 2) connected to slave_B.

Tests mbist_test_A and scan_test_B are characterized as requiring 800 test cycles and 900 test cycles respectively (One test cycle equals one period of the system clock, namely source_clock (113) of FIG. 1). Since the two test lengths are nearly identical, each UTN data packet is set to have two slots, slot number 0 for block_A and slot number 1 for block_B. The operations of the example are described below with reference to states of the FSM in master controller 320, described above and timing diagrams. The UTN slave ring connection-order in the example is as follows:

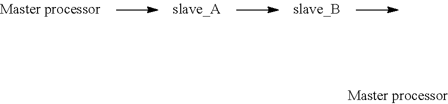

The test patterns are generated using test pattern generator software, described in section 16 below. These patterns are loaded into the Automatic Test Equipment (ATE). The ATE performs the following operations sequentially:

### Phase I: Configure UTN Master

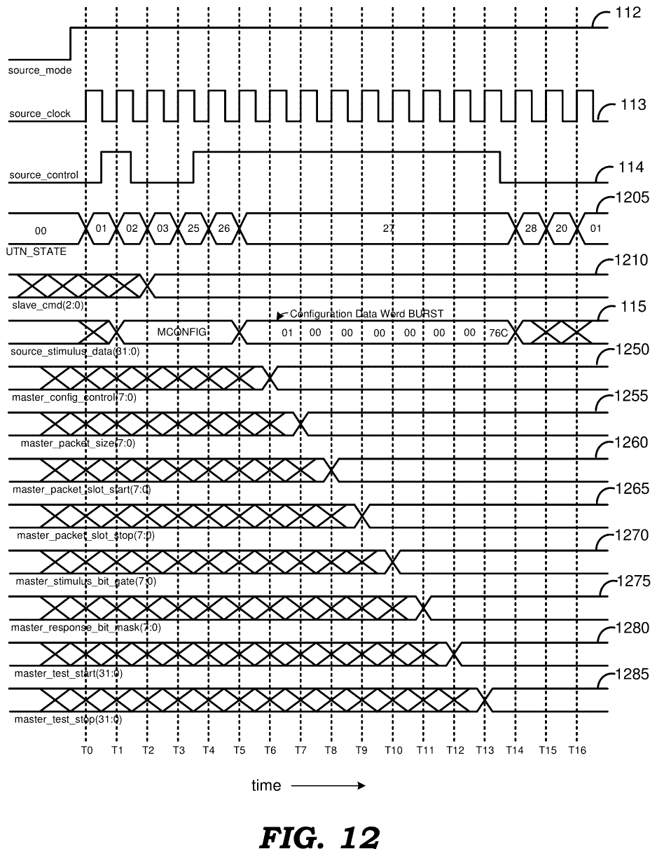

In this phase, configuration registers of the UTN Master processor are programmed. This phase also sets a register bit that enables the Master processor, loads packet size register, packet slot start index and packet slot stop index. FIG. 12 is a timing diagram illustrating the operations in this phase. The description below is provided with combined reference to FIG. 10 and FIG. 12.

Prior to the commencement of the test session, source_mode (112) is at logic 0, indicating that the SOC is in the mission or normal/functional mode.

Sometime shortly before time instant T0, the ATE asserts source_mode (112) to logic 1, and starts free-running system clock (source_clock) 113, which is shown as transitioning to logic 1 at T0. Source_clock is active at least till the end of the test session. Transition of source_mode (112) to logic 1 causes the FSM to transition from Master Reset (00) state to Instruction Polling (01) state, as indicated by the values 00 and 01 of UTN_STATE waveform (1205). Although not indicated in FIG. 12, following the change in state, the FSM remains in state 01 for 100 cycles of source_clock (113) for the reset and source_clock (113) to propagate throughout the UTN network (including slave_A and slave_B).

Approximately midway between time T0 and T1, the ATE asserts source_control (114) to logic 1 and applies instruction code MCONFIG (Master configuration registers programming) on bus source_stimulus_data (115). As a result, the FSM changes to state Instruction Load (02) at time T1 (rising edge of source_clock (113)). Accordingly, the instruction code MCONFIG is loaded from bus source_stimulus_data (115) into the stimulus data register of the master packet manager. During the following clock rising edge at T2, this instruction code is transferred to the instruction register in the master controller (320 in FIG. 3).

Approximately midway between time T1 and T2, the ATE asserts source_control (114) to logic 0. At time T2, the FSM transitions to Instruction Decode (03) state. Since the loaded instruction is MCONFIG, the FSM transitions to MCONFIG state (25) in response to the next rising clock edge at time T3. The FSM stays in state (25) for as long as source_control (114) is at logic 0.

Approximately midway between time T3 and T4, the ATE applies a logic 1 on source_control (114), causing the FSM to change state from MCONFIG to MCONFIG START (26) at time T4. The FSM changes to state MCONFIG LOAD (27) at T5. In this state, the relevant configuration registers (380 in FIG. 3) of the master are set to desired values.

Accordingly, the ATE applies the desired values for the master configuration registers on bus source_stimulus_data (115) one cycle at a time, as indicated by the corresponding values in waveform 115 in the interval T6 to T14. Since in the example, only one SOC is involved in the test, most of the master configuration registers are loaded with default values, as noted below. In the example, 8 configurations registers of the master processor are shown being initialized. Waveforms 1250, 1255, 1260, 1265, 1270, 1275, 1280 and 1285 represent the sequential initialization of the corresponding registers with the values noted below. Each register is written at a corresponding rising edge of source_clock (113) as indicated by the waveforms in FIG. 12. The values loaded in the 8 registers as well as the function of the register are noted below:
i. master_config_control[7:0]: This register enables the master for active testing. To achieve this purpose, value 8′h01 (eight-bit hexadecimal value of 01) is loaded in this register. This register is loaded at time T6.
ii. master_packet_size[7:0]: This register holds packet size. The packet size is given in terms of the number of timing slots (or source_clock cycles). As there is only one SOC in the test, packet size at master processor level does not apply. Hence, 8′h00 is loaded in this register at time T7.
iii. Master_packet_slot_start[7:0]: This register indicates the data slot start index for master processor. For a single-SOC test set-up, this register is loaded with 8′h00 at time T8.
iv. Master_packet_slot_stop[7:0]: This register indicates the data slot end index for master processor. For a single-SOC test set-up, this register is loaded with 8′h00 at time T9.
v. Master_stimulus_bit_gate[7:0]: This register is used to gate-off any undesired bits from bus source_stimulus_data (115). In the example, no gate-off is needed, and the default value of 8′h00 is loaded in this register at time T10.
vi. Master_response_bit_mask[7:0]: This register is used to mask some selected bits from response data from a functional block before sending it to the ATE. In the example, no masking is required and the default value of 8′h00 is loaded in this register at T11.
vii. Master_test_start[31:0]: This is a 32-bit register and holds the value of the number of cycles of source_clock (113) from which the test execution starts after loading STESTEXE instruction. This feature provides a mechanism to delay the test execution for a particular number of cycles. In the example, no delay is used, and this register is loaded with 32′h0 at T12. Four words are needed to load this 32-bit register.
viii. Master_test_stop[31:0]: This is a 32-bit register and holds the value of the number of cycles of source_clock (113) after which test execution stops. Since a total of 900 packets are needed to complete all the tests noted above, and each packet has 2 slots, 1900 (950×2) source_clock cycles are needed for the entire test. The number 1900, rather than 1800 (900×2), is used because some additional cycles are needed to account for operation of pipeline stages of the stimulus/response data path. Hence, 32′h76C (76C is the hexadecimal equivalent of the decimal value 1900) is programmed in this register.

By the end of time T13, all the relevant master configuration registers are programmed with the desired values. The ATE applies a logic 0 on source-control (114) sometime midway between T13 and T14, and the FSM transitions to state MCONFIG DONE (28) at T14, indicating the end of instruction execution.

The FSM then advances to Master Wait (20) state at time T15. Source_control (114) continues to remain at logic 0 at T16 causing the FSM to transition to state Instruction Polling (01). The FSM waits in state (01) for the next instruction.

### Phase II: Assigning Slave IDs to Slave Unit of the SOC

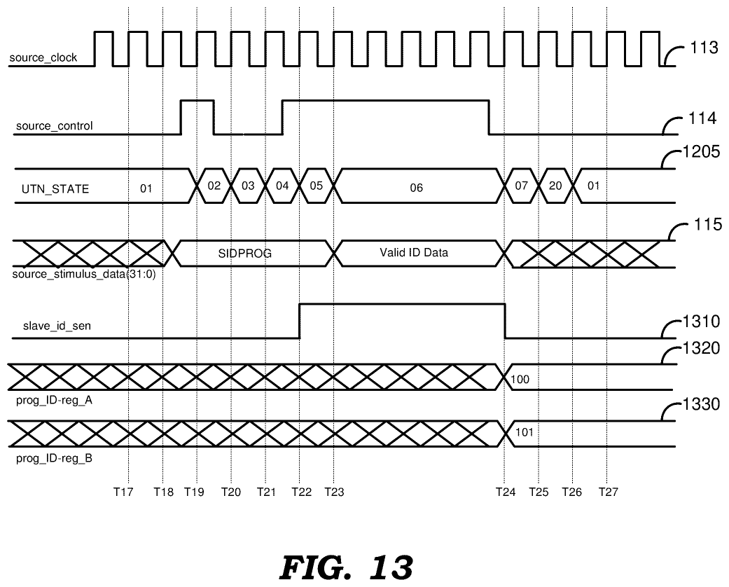

In this phase, slave ID registers of the two slaves are programmed. The slave IDs are generated during pattern generation process and loaded in the ATE. The slave IDs are generated on a per-test-session basis based on the number of slave units in the UTN slave ring. FIG. 13 is a timing diagram illustrating the operations in this phase. The description below is provided with combined reference to FIG. 10 and FIG. 13. The FSM is in Instruction Polling (01) state at the beginning of this phase, as indicated by the value (01) in waveform 1205.

Sometime midway between time T18 and T19, the ATE drives source_control (114) to a logic 1, and applies the code for instruction SIDPROG (Slave ID Program) on bus source_stimulus_data (115). As a result, the FSM transitions to state Instruction Load (02) and the instruction code SIDPROG is loaded from bus source_stimulus_data (115) into the instruction register in the master controller.

The ATE applies a logic 0 on source_control (114) sometime midway between T19 and T20, causing the FSM to transition to state Instruction Decode (03) at T20. At T21, the FSM transitions to state SIDPROG (04) state.

The ATE applies a logic 1 on source_control (114) sometime midway between time T21 and T22, and the FSM transitions to state SIDPROG START (05) at T22. At T22, the master drives enable signal slave_id_sen (214 in FIG. 3) to logic 1, thereby causing all the slave ID registers to be configured as a shift register (as described above with respect to FIG. 11). The slave ID bits can now be shifted into the shift register formed by the slave ID registers of slave_A and slave_B.

The FSM advances to state SIDPROG RUN (06) at T23 and the ATE sends the slave ID data on bus source_stimulus_data (115). Since only one slave ID chain is present in the example, only one bit (e.g., least significant bit) of bus source_stimulus_data (115) is used for slave ID programming. This serialization of the slave IDs on the multi-bit stimulus data bus (115) itself obviates the need at the master for circuitry to convert multi-bit data to serial form. The programming of the slave ID registers of slave_A and slave_B is complete by T24.

The ATE applies a logic 0 on source_control (114) prior to time T24, and the FSM transitions to state SIDPROG DONE (07) at T24 indicating the completion of SIDPROG instruction. In state (07), the master controller drives slave_id_sen to logic 0, which is shown occurring at T24. With slave_id_sen at logic 0, the slave ID register values cannot change. In the example, the programmed slave IDs are 100 for slave A and for 101 for slave B, as indicated in respective waveforms 1320 and 1330 following time T24. Slave ID are assigned starting from 100 to 4095 (12 bit-slave ID is used) in an embodiment. Slave IDs from 0 to 99 are reserved for future internal use.

The ATE maintains a logic 0 on source_control (114) for two more cycles of source_clock (113) cycles, causing the FSM to transition to state (07) at T24, state (20) at T25 and state (01) at T26, at which point Phase II ends.

### Phase III: Configuring Slave Setup Registers

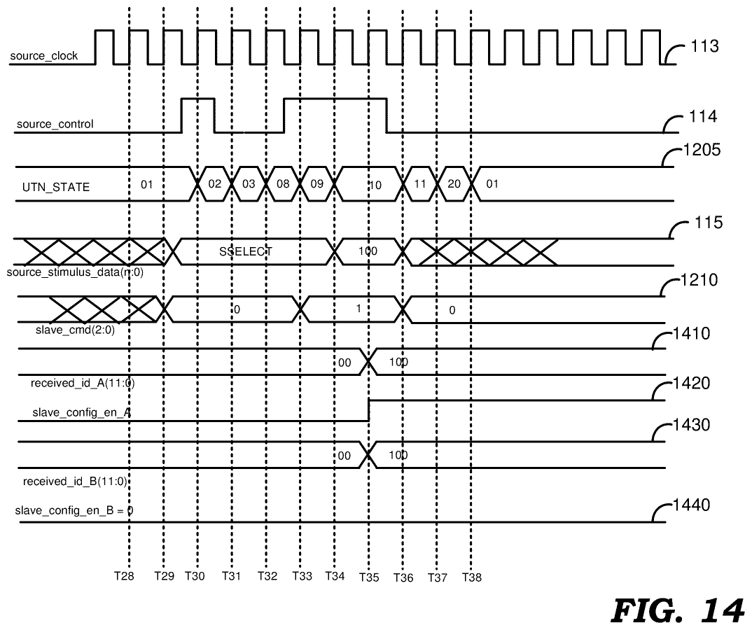

In this phase, the relevant configuration registers of slave_A and slave_B are programmed. The configuration of the registers of slave_A is completely done first, followed by that of slave_B. In general, this phase, configuration of slave registers, is repeated (with the corresponding values) for each slave that is part of the test set-up. FIG. 14 is a timing diagram illustrating the operations in the configuration of the setup registers of slave_A. The description below is provided with combined reference to FIG. 10 and FIG. 14. The FSM is in Instruction Polling (01) state at the beginning of this phase, as indicated by the value (01) in waveform 1205.

Configuring slave_A:

### Part-1: Slave_A is First Enabled Prior to Configuration of its Registers.

The ATE applies a logic 1 to source_control (114), and sends instruction code SSELECT(Slave Select for configuration programming) on bus source_stimulus_data (115). The FSM transitions through states 02 and 03 as described above with respect to the earlier phases, and the description is not repeated here. Further, the state transitions occur in response to the appropriate state of source_control (114) and at rising edges of source_clock (113) as illustrated above, and detailed references to the logic states/edges of signals 114 and 113 are not made again when noting state changes of the FSM.

The FSM reaches state SSELECT (08) at time T32. The master (or the FSM) applies the value 0 on command bus slave_cmd (1210).

The FSM transitions to SSELECT START (09) at time T33. In this state, the FSM drives a value 1 on bus slave_cmd (1210). In response to the value 1 on slave_cmd (1210), all the slaves (here slave_A and slave_B) are set to sample the slave ID to be broadcast in the next two clock cycles on source_stimulus_data (115)).

At T34, the FSM transitions to the state SSELECT RUN (10) and the ATE will broadcast the slave ID of slave_A (programmed to be 100 in the previous phase described above) on bus source_stimulus_data (115). In FIG. 14, the value 100 is shown available on bus 115 starting at T34, and remains on the bus for two cycles of source_clock (113), since the value has to pass through slave_A and reach and be available at slave_B (which occurs at T35). At T35, both slaves have receipt of the broadcast slave ID of 100, and waveforms 1410 and 1430 show the value 100 as having been loaded into respective ‘receive id’ registers in slave_A and slave_B.

The FSM transitions to state SSELECT DONE (11) at T36. In this state, the master applies the value 0 on bus slave_cmd[2:0](1210). Also in this state, each of slave_A and slave_B compares the ID in its received_id register with the programmed slave ID. The slave unit with the matching ID (here slave_A) asserts slave_config_en_A (1420) signal at time T35, indicating that slave_A is ready to receive configuration data. The FSM then transitions through states (11) and (20) back to (01), the Instruction Polling state.

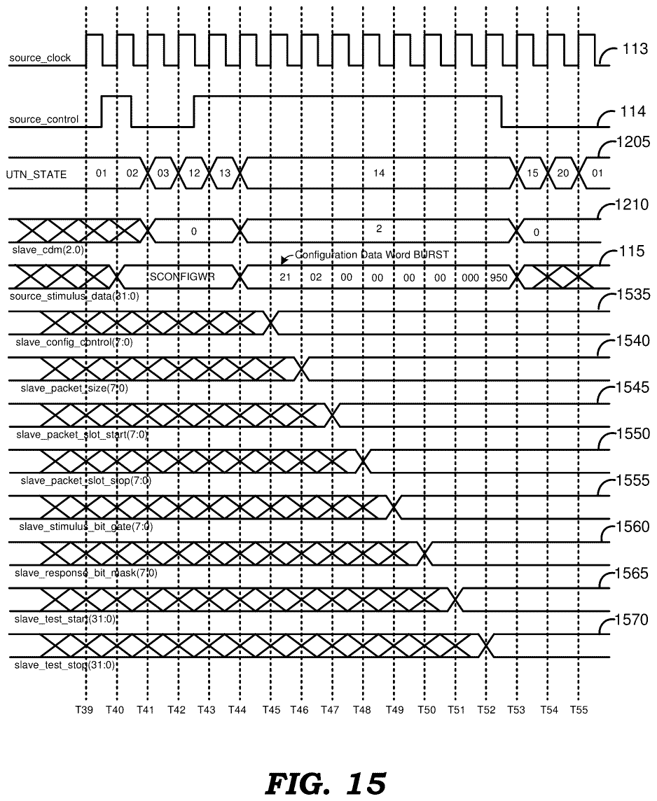

Part-2: ‘Slave configuration register write’ (SCONFIGWR) instruction is executed, and the configuration registers of slave_A are programmed. FIG. 15 is a timing diagram illustrating the configuration of the registers of slave_A. Only slave_A will respond to the configuration data since slave_A was selected previously. Slave_B will ignore the data.

The ATE drives a logic 1 on source_control (114) and applies instruction code for SCONFIGWR (Slave Configuration Write) on bus source_stimulus_data (115). The FSM transitions through states (02) and (03) to reach state SCONFIGWR (12) at T42. With the FSM in state SCONFIGWR, the ATE applies a logic 1 to source_control (114). The FSM transitions to SCONFIG START (13) state at T43. In this state, master drives the value 2 on bus slave_cmd[2:0](1210). The value 2 on slave_cmd (1210) enables configuration-write operation on slave_A (the slave that was enabled in Part-1 (noted above) of the slave register configuration phase.

The FSM transitions to state SCONFIG RUN (14) at T44, and the ATE transmits slave register configuration data for slave_A on bus source_stimulus_data (115). The ATE transmits configuration data in the following order (and indicated in FIG. 15 by respective waveforms 1535, 1540, 1545, 1550, 1555, 1560, 1565 and 1570):
slave_config_control[7:0]: 8′h21 at time T45. The value 21 indicates: Turn-on the slave and select IEEE 1500 WTAP bridge for memory testing.
slave_packet_size[7:0]: 8′h02 at time T46. A packet has 2 slots.
slave_packet_slot start[7:0]: 8′h00 at time T47. Slave_A's slot starts from index 0.
slave_packet_slot_stop[7:0]: 8′h00 at time T48. Slave_A's slot ends at index 0. Thus, slave_A has been assigned one slot per packet and its slot index is 0 in the packet.
slave_stimulus_bit_gate[7:0]: 8′h00 at T49. All input bits of the slot are consumed by slave_A.
slave_response_bit_mask[7:0]: 8′h00 at T50. All output bits of the slot are consumed by slave_A.
slave_test_start[31:0]: 32′h0 at T51. Test mbist_test_A starts from packet number 0.
slave_test_stop[31:0]: 32′h320 at T52. (320 is the hexadecimal equivalent of decimal 800). mbist_test_A stops at packet number 800.

All the configuration registers of slave_A are configured by time T53. The ATE applies a logic 1 on source_control (114) to exit the SCONFIG RUN (14) state, and the FSM transitions to the next state SCONFIG DONE (15) at time T53. In this state, the master applies the value 0 on slave_cmd[2:0](1210).

The FSM then transitions through state (20) to reach state (01), the Instruction Polling state at T55. The programming phase of slave configuration registers of slave_A is now complete.

Configuring slave_B: Although the corresponding waveforms are not shown for slave_B, programming sequences similar to those noted above and listed under in Part-1 and Part-2 for slave_A are performed to program configuration registers of slave_B. The corresponding operations are briefly noted below:
Part-1: The ATE issues instructions and data to broadcast slave_B's slave ID (programmed previously as 101).
Part-2: The following configuration register of slave_B are programmed with the corresponding values noted there:
slave_config_control[7:0]: 8′h31. The value 31 indicates: Turn-on this slave and select the Scan interface bridge for scan-testing.
slave_packet_size[7:0]: 8′h02. A packet has 2 slots.
slave_packet_[7:0]: 8′h01. Slave_B's slot starts from index 1.
slave_packet_[7:0]: 8′h01. Slave_B's slot ends at index 1. Thus, slave_B has been assigned one slot per packet and the slot index is 1.
slave_stimulus_bit_gate[7:0]: 8′h00. All input bits of the slot are consumed by slave_B.
slave_response_bit_mask[7:0]: 8′h00. All output bits of the slot are consumed by slave_B.
slave_test_start[31:0]: 32′h0. Test scan_test_B starts from packet number 0.
slave_test_stop[31:0]: 32′h384 (384 is the hexadecimal equivalent of decimal 900). scan_test_B stops at packet number 900.

The FSM then transitions from SCONFIG DONE state to Instruction Polling state. At this point, both the slaves A and B are configured and ready to start the test execution.

### Phase IV: Test Execution Phase

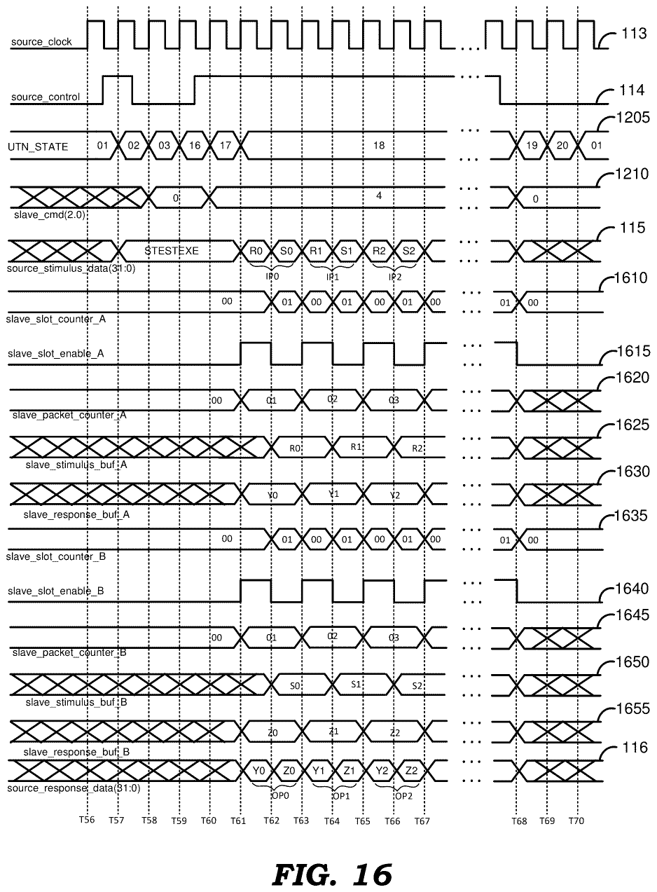

In this phase, the two tests mbist_test_A and scan_test_B are performed concurrently. Input data and output data will be delivered in packets. FIG. 16 is a timing diagram illustrating the operations in this phase. In the interest of conciseness, only the key operations and event of those illustrated in FIG. 15 are noted below, the rest being similar to corresponding operations/events described in the other phases above.

The ATE drives a logic 1 on source_control (114), and applies instruction code STESTEXE (Slave Test Execution) on bus source_stimulus_data (115). The FSM transitions to Instruction Load (02) state on the rising edge of source_clock (113) at time T57. In this state, the instruction code STESTEXE is loaded from source_stimulus_data (115) into the instruction register of the master controller. The ATE continues to maintain source_control (114) at logic 0 for the next two clock cycles. The FSM transitions to state STESTEXE (16) at time T59.

Before the next rising edge of source_clock (113) at T60, the ATE drives a logic 1 on source_control (114). The FSM transitions to state STESTEXE START (17) at time T60. In this state, the master applies the value 4 on bus slave_cmd[2:0] (1210). The value 4 is an indication to slaves A and B to initiate de-assertion of reset for their packet slot counters in a synchronized fashion. Also, value 4 enables operation of the corresponding bridge selected in each slave.

The FSM then transitions from state STESTEXE START(17) to state STESTEXE RUN(18). At time T61, delivery of input test data packets (by the ATE) starts on source_stimulus_data (115) and receipt by the ATE of response data from the functional blocks (to the corresponding stimulus data) starts on source_response_data (116). This process continues till all the test data packets are delivered and the responses sampled. In this example, 900 test data packets are applied. It is note here that the input test data packets (IP0, IP1, IP2, etc. in the Figure) include both configuration data to configure the corresponding functional blocks for the test, as well as stimulus data.

After the last test data packet is processed, the ATE applies a logic 0 on source_control (114). In response, the FSM transitions from state STESTEXE RUN (18) to state STESTEXE DONE (19) at time T68. The STESTEXE DONE (19) state causes the master to apply the value 0 on slave_cmd[2:0] (1210), signaling the end of execution of the STESTEXE instruction.

The FSM then transitions through state (20) back to state (01). This is the end of one test session. Now, the UTN can be reconfigured to run another test session.

Some technical details regarding operations in a slave during the STESTEXE instruction are noted next with reference to the timing diagram of FIG. 16.

Stimulus data for tests are applied only in Phase-IV while executing instruction STESTEXE.

Input (stimulus) data packet: In the example, stimulus data packets have 2 slots each and are delivered on bus source_stimulus_data (115). In waveform 115 of FIG. 16, stimulus data packets are labelled IP0, IP1, IP2, . . . IPx. Each packet has two slots—slot 0 and slot 1. Slot 0 carries stimulus data words (R0, R1, R2, . . . Rx) for slave_A and slot 1 carries stimulus data words (S0, S1, S2, . . . Sx) for slave_B.

Output (response) data packet: In the example, response data packets also have 2 slots each and are delivered on bus source_response_data (116). In waveform 116 of FIG. 16, response (output) packets are labelled OP0, OP1, OP2, . . . OPx. Each packet has two slots—slot 0 and slot 1. Slot 0 carries response data words (Y0, Y1, Y2, . . . Yx) from slave A and slot 1 carries response data words (Z0, Z1, Z2, . . . Zx) from slave B.

Slave slot counter: Each slave contains a slot counter. Waveforms 1610 and 1635 respectively depict the contents in the slot counters of slave_A and slave_B respectively. The slot counter of each slave starts counting once the value 4 is applied by master controller on slave_cmd (1210). Slot counters start counting from 0 and continue counting till the count value reaches the packet size limit (900 in the example). Once the counter value reaches the packet size limit, the slot counter rolls over to 0 and starts counting again. The packet size limit is programmed in register slave_packet_size. Both of the slot counters of slave_A and slave_B start counting from time T62. Such synchronization is achieved by setting the value on bus slave_cmd[2:0] to 4, in the example.

Slave slot enable: Each slave receives a slave_slot_enable signal. In FIG. 16, enable signals slave_slot_enable_A (1615) and slave_slot_enable_B (1640) are the slave slot enable signals of slave A and slave B respectively. Each time the value of slave slot counter matches the value in the slave_packet_slot_start register, slave_slot_enable is asserted to logic 1 for one cycle of source_clock (113). In response to this logic 1 pulse on slave_slot_enable, the corresponding slave samples data on bus source_stimulus_data (115) (or more precisely, its input slave_stimulus_data (217) in FIG. 4) and loads this data into a local buffer named slave_stimulus_buf. In FIG. 16, these local stimulus buffers in slave_A and slave_B are respectively named slave_stimulus_buf_A (waveform 1625) and slave_stimulus_buf_B (waveform 1650).

After sampling of the stimulus data in a slot, a slave inserts a response word from a local buffer slave_response_buf into its slave_response_data output (226 in FIG. 4) in the same slot. The response data on the slave's slave_response_data output reaches response bus source_response_data (116). In FIG. 16, these local response buffers are named slave_response_buf_A (waveform 1630) and slave_response_buf_B (waveform 1655). It can be observed from FIG. 16 that data rate from/to a slave (see waveforms 1625, 1630, 1650 and 1655 in FIG. 16) is half that on buses source_stimulus_data (115) and source_response_data (116).

Slave packet counter: Each slave has one 32-bit packet counter. The packet counter for a session starts at 0 and increments by 1 every time a logic 1 pulse appears on slave_slot_enable signal, as depicted in waveforms 1620 and 1645. The slave packet counter values in slaves increment at the same rate during a test session, as may be observed from waveforms 1620 and 1645. The reason for this is that each slave receives data in its own slot in every packet, and also receives the same total number of packets in a test session. However, the slaves might be assigned an unequal number of slots per packet depending on their test requirements, as described above.

Running mbist_test_A on Slave_A:

Slave_A's packet manager extracts the slot-0 data from every packet and passes it to its IEEE 1500 bridge (e.g., such as 232 in FIG. 2). The IEEE 1500 bridge converts this UTN word (i.e., the data) to the form (corresponding data and/or signals) required by the IEEE 1500 standard. These data and/or signals so generated by the bridge then drive control signals of the memory BIST controller in the tested functional block (memory) in slave_A. The memory controller also sends results of the test such as pass/fail, type of test done and diagnostic data back to the IEEE 1500 bridge. In turn, the bridge sends the results as response data back to slave_A's packet manager, which then forwards the response data on its response data bus in the same slot to the master. The ATE receives the response data from the master on the source_response_data bus (116), and processes the response data in a suitable manner.

Slave_A continues processing packets till the packet count equals 800, after which slave_A stops all packet processing and goes into the ‘test idle’ state. Slave_A continues in this state till the master (the FSM) completes the execution of the STESTEXE instruction.

### Concurrently Running Scan_Test_B on Slave_B:

Slave_B's packet manager extracts the slot-1 data from every packet and passes it it's scan interface bridge (e.g., such as 233 of FIG. 2). The scan interface bridge converts this UTN word into scan test interface signals such as scan_enable, scan_clock, scan_in, scan_out, TDI, TRST, TCK, TMS, and TDO. These signals perform scan setup and scan load-unload as well as scan capture operations. The scan unload data (response data) is converted back to a UTN word from by the scan interface bridge, and forwarded to slave_B's packet manager, which forwards the response data on its response data bus in the same slot to the master. The ATE receives the response data from the master on the source_response_data bus (116), and processes the response data in a suitable manner.

Slave_B continues processing packets till the packet count reaches 900, after which slave_B stops all packet processing and goes into the ‘test idle’ state. Slave_B continues in this state till the master completes execution of the STESTEXE instruction, which occurs in response to the master packet counter reaches 900.

### 15. Salient Features of UTN

The following features and capabilities of the UTN may be appreciated from the foregoing description:
1) UTN provides a high-speed, parallel and homogeneous interface from system level to block level.
2) Highly scalable in terms of parallel data bus width. This can be implemented using minimum 5 pins to maximum 100 pins based on available pins in each SOC.
3) Smart Master Processing Unit:
   Master processing unit has built-in smart instruction processor (the FSM in master controller 320, described above). This processor can execute multiple instructions to complete several tasks internally. It can perform self-setup using variety of instructions and source_control signal. This avoids need of any other interface required to setup UTN. Thus, UTN is self-sufficient to program itself as well as run all type of tests.
4) Dynamic slave ID programming:
   This feature enables run time ID allocation to each slave unit in the network. This eliminates need of hard coding of ID for each slave unit during design phase. This allows reuse of previously taped out IP/blocks without any modifications. Also, this feature eliminates possibilities of slave ID duplication for multiple IPs/blocks.
5) Smart and simple method to synchronize data packet processing across all the slave units. This is done by sending a ‘sync’ trigger on slave_cmd bus and maintaining equal pipeline stages between slave_cmd and slave_stimulus_data buses.
6) Within a SOC, the number of signals required between master processor and a slave unit is fixed. This feature allows integration of any number of slave units inside a SOC without need for any additional control or data signals from master processor. This makes integration, routing and timing closure very easy. In contrast, current IEEE 1149.1+IEEE 1500 based interface requires dedicated one select signal and one serial data output per IP and blocks. This makes the number of signals needed directly proportional to number of blocks/IPs present in SOC.
7) Enables concurrent test application:
   One data packet can contain many slots using TDM (Time Division Multiplexing) scheme. These slots can be sent to multiple slave units using same data packet. Each slave unit executes test independently. Hence each block can run different types of tests concurrently. Thus, UTN allows all structural and functional tests to run concurrently with each other. This reduces test time significantly and utilizes ATE resources very efficiently.
8) Minimizes test storage space and test application time:
   UTN provides packet slot sharing technique, word sharing technique, and Frozen Packet technique to minimize Automatic Test Equipment (ATE) storage memory requirements as well as test application time. This reduces test cost significantly.
9) 2.5D and 3D testing:
   UTN very efficiently addresses this issue using simple daisy chains connections of data path and independent source_control signal for each die.
10) Protocol Bridges:
   The protocol bridges are connected to slave units. These bridges can map UTN packet data to any target interface. These interfaces can be IEEE 11410.1, IEEE 1500, IEEE 1687, Scan bus, SPI, I2C or any other custom functional buses.

It may thus be appreciated that UTN provides a high-speed, multitasking, scalable and versatile test network.

The description is continued with the details of an ATE in an embodiment.

### 16. Automated Test Equipment for UTN

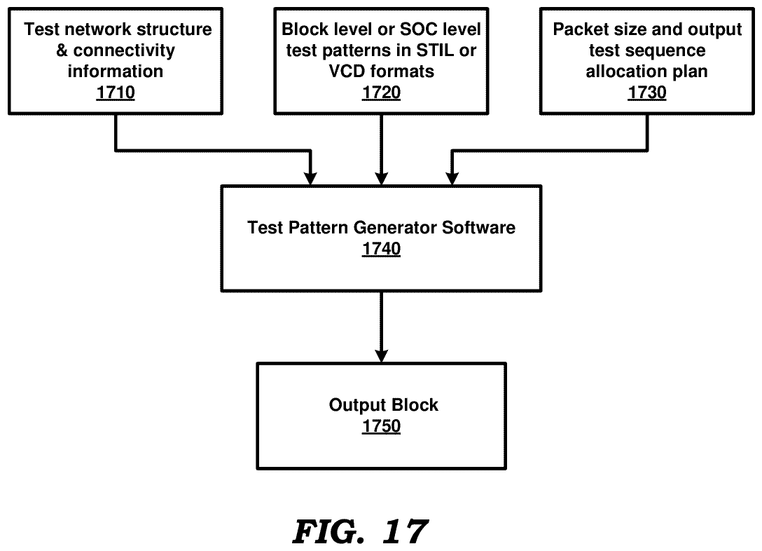

FIG. 17 is a block diagram illustrating the manner in which test patterns for a test are generated using UTN pattern generator EDA (electronic design automation) software in an embodiment. This software generates all the sequences noted above in section 14.

UTN (or Test) pattern generator software (1740) is designed to generate test patterns using conventional patterns output by commercial DFT (Design for Test) tools or dumped in value change dump (VCD) format during functional simulations. Test Pattern generator software (1740) receives inputs from three blocks—1710, 1720 and 1730. Test pattern generator software (1740) may generate multiple test-pattern files, with each file containing the test patterns for a corresponding type of test such as BIST, scan test and functional test.

Test network structure information 1710 is a file that contains complete information describing the test network. The information includes parameters such as word size, the number of slaves connected in a slave ring and the order of the slaves in the ring starting from the master. This information is written out by a UTN insertion tool that inserts UTN master processor and slave units as well as connects the slave units in a slave ring.

Source test patterns 1720 contains test patterns written out by standard commercial DFT tools (such as Memory BIST, Logic BIST, ATPG, JTAG etc.) in P1450.1 IEEE Standard Test Interface Language (STIL) format. Test patterns 1720 may also contain functional test patterns generated in VCD format by functional verification process.

Test sequence allocation plan 1730 is a file in which a user provides details of the test plan as well as packet size in terms of source_clock (113) cycles. The test plan specifies, among others, the number of slaves that will be active in a given test session, the nature/type of test(s) to be performed on the slaves as well as slot allocation information of each slave.

Output block 1750 parses the multiple test pattern files generated by block 1740 and extracts cycle-by-cycle pin value details for each test. The main function of this block is to merge all the individual test patterns and create a single UTN-packets-based test, i.e., convert/map the test patterns into a form that is compatible with the UTN architecture. Output block 1750 generates a merged test based on test packet size and test slot allocation information provided by a user and generates slave IDs for the slaves in the slave ring based on slave-ring information. Output block 1750 writes out merged UTN tests in STIL (IEEE Standard Test Interface Language (STIL) for Digital Test Vector Data Design Extension) and Verilog formats. The ATE (or a software module in the ATE) transmits, on the signal interface shown in FIG. 1 for example, the STIL format patterns to the test network in an SOC or system to carry out post-fabrication screening of the fabricated SOCs. The Verilog format patterns can be used to perform pre-silicon verification using standard HDL simulators.

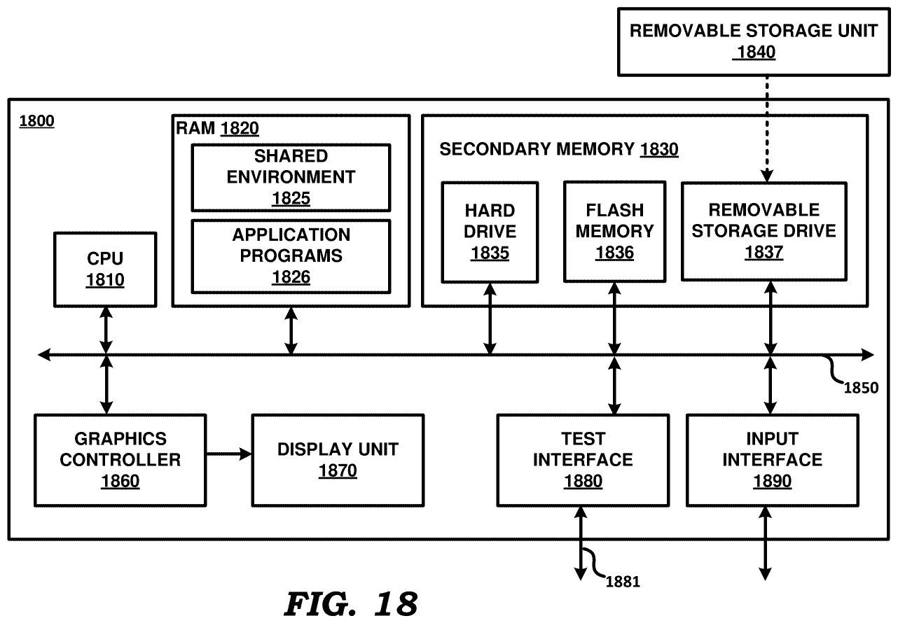

FIG. 18 is a block diagram illustrating the details of digital processing system 1800 representing an ATE (110 of FIG. 1), and in which several aspects of the present disclosure are operative by execution of appropriate executable modules.

Digital processing system 1800 may contain one or more processors such as a central processing unit (CPU) 1810, random access memory (RAM) 1820, secondary memory 1830, graphics controller 1860, display unit 1870, test interface 1880, and input interface 1890. All the components except display unit 1870 may communicate with each other over communication path 1850, which may contain several buses as is well known in the relevant arts. The components of FIG. 18 are described below in further detail.

CPU 1810 (including any specific hardware specific to machine learning, etc.) may execute instructions stored in RAM 1820 to provide several features of the present disclosure. CPU 1810 may contain multiple processing units, with each processing unit potentially being designed for a specific task. Alternatively, CPU 1810 may contain only a single general-purpose processing unit.

RAM 1820 may receive instructions from secondary memory 1830 using communication path 1850. RAM 1820 is shown currently containing software instructions constituting shared environment 1825 and/or other user programs 1826 (such as other test programs). User programs 1826 includes the output generated by output block 1750 of FIG. 17, described above. In addition to shared environment 1825, RAM 1820 may contain other software programs such as device drivers, etc., which provide a (common) run time environment for execution of other/user programs.

Graphics controller 1860 generates display signals (e.g., in RGB format) to display unit 1870 based on data/instructions received from CPU 1810. Display unit 1870 contains a display screen to display the images defined by the display signals. Input interface 1890 may correspond to a keyboard and a pointing device (e.g., touch-pad, mouse) and may be used to provide inputs.

Test interface 1880 provides connectivity to a system or an SOC, and contains the circuitry and pins/ports for generating and providing/receiving the signals shown in FIG. 1. Thus, the signals from ATE 110 to SOC 120 in FIG. 1 are contained in path 1881.

Secondary memory 1830 may contain hard drive 1835, flash memory 1836, and removable storage drive 1837. Secondary memory 1830 may store the data (e.g., test patterns) and software instructions (e.g., representing test programs/routines), which enable digital processing system 1800 to provide several features in accordance with the present disclosure. The code/instructions stored in secondary memory 1830 may either be copied to RAM 1820 prior to execution by CPU 1810 for higher execution speeds, or may be directly executed by CPU 1810.

Some or all of the data and instructions may be provided on removable storage unit 1840, and the data and instructions may be read and provided by removable storage drive 1837 to CPU 1810. Removable storage unit 1840 may be implemented using medium and storage format compatible with removable storage drive 1837 such that removable storage drive 1837 can read the data and instructions. Thus, removable storage unit 1840 includes a computer readable (storage) medium having stored therein computer software and/or data. However, the computer (or machine, in general) readable medium can be in other forms (e.g., non-removable, random access, etc.).

In this document, the term “computer program product” is used to generally refer to removable storage unit 1840 or hard disk installed in hard drive 1835. These computer program products are means for providing software to digital processing system 1800. CPU 1810 may retrieve the software instructions, and execute the instructions to provide various features of the present disclosure described above.

The term “storage media/medium” as used herein refers to any non-transitory media that store data and/or instructions that cause a machine to operate in a specific fashion. Such storage media may comprise non-volatile media and/or volatile media. Non-volatile media includes, for example, optical disks, magnetic disks, or solid-state drives, such as storage memory 1830. Volatile media includes dynamic memory, such as RAM 1820. Common forms of storage media include, for example, a floppy disk, a flexible disk, hard disk, solid-state drive, magnetic tape, or any other magnetic data storage medium, a CD-ROM, any other optical data storage medium, any physical medium with patterns of holes, a RAM, a PROM, and EPROM, a FLASH-EPROM, NVRAM, any other memory chip or cartridge.

Storage media is distinct from but may be used in conjunction with transmission media. Transmission media participates in transferring information between storage media. For example, transmission media includes coaxial cables, copper wire and fiber optics, including the wires that comprise bus 1850. Transmission media can also take the form of acoustic or light waves, such as those generated during radio-wave and infra-red data communications.

### 17. Conclusion

References throughout this specification to “one embodiment”, “an embodiment”, or similar language means that a particular feature, structure, or characteristic described in connection with the embodiment is included in at least one embodiment of the present disclosure. Thus, appearances of the phrases “in one embodiment”, “in an embodiment” and similar language throughout this specification may, but do not necessarily, all refer to the same embodiment.

While in the illustrations of FIGS. 1 through 6, 11 and 18, although terminals/nodes are shown with direct connections to (i.e., “connected to”) various other terminals, it should be appreciated that additional components (as suited for the specific environment) may also be present in the path, and accordingly the connections may be viewed as being “electrically coupled” to the same connected terminals.

While various embodiments of the present disclosure have been described above, it should be understood that they have been presented by way of example only, and not limitation. Thus, the breadth and scope of the present disclosure should not be limited by any of the above-described embodiments, but should be defined only in accordance with the following claims and their equivalents.

What is claimed is:

1. An electronic system comprising:
a plurality of functional blocks;
a plurality of slave units, with each functional block being coupled to one of said plurality of slave units;
a master processor to receive test instructions and data units as a basis for a plurality of tests from a test equipment, wherein said test equipment indicates a corresponding slave unit to which each test is directed to,
said master processor causing execution of each test on corresponding functional block based on the test instructions and data units corresponding to the test by interfacing with a respective slave unit as indicated by said test equipment.

2. The electronic system of claim 1, wherein said master processor receives a first set of test instructions and a first set of data units as a basis for a first test directed to a first slave unit starting from a first time instance and said first slave unit completes executing said first test by a second time instance, wherein a first duration is constituted between said first time instance and said second time instance,
wherein said master processor receives a second set of test instructions and a second set of data units as a basis for a second test directed to a second slave unit starting from a third time instance and completes executing said second test by a fourth time instance, wherein a second duration is constituted between said third time instance and said fourth time instance,
wherein said first duration overlaps with said second duration such that first test is performed concurrent with said second test at least in part.

3. The electronic system of claim 2, further comprising a plurality of bridges driven by each slave unit, wherein each bridge is designed to interface with the corresponding functional block according to a protocol standard for one of a structural test and a functional test,
wherein said master processor generates a corresponding set of commands for each instruction of said first set of test instructions and said second set of test instructions, said master processor to forward said corresponding set of commands to the corresponding slave,
said corresponding slave responding to the sets of commands to receive said first set of data units and to forward the received data units to the corresponding bridge.

4. The electronic system of claim 3, wherein said first set of test instructions and said second set of test instructions are formed of a set of instruction types comprising master configure, slave configure, setting slave identifiers, and a start test,
wherein said master-configure instruction causes a set of configuration registers in said master to be configured based on data received from said test equipment,
wherein said slave configure causes a set of configuration registers in a specific slave to be configured based on data received from said test equipment,
wherein said setting slave identifiers causes said master to issue commands to program respective slave identifier registers of said plurality of slaves to be configured with corresponding identifiers received from said test equipment, and
wherein said start test causes said master to issue commands to said plurality of slaves to commence receiving corresponding sets of data for performing respective tests.

5. The electronic system of claim 4, wherein said master processor and said plurality of slave units are coupled sequentially in the form of a daisy-chain such that said master sends data units and commands to all of said plurality of slave units via a head slave of said daisy chain and receive results of testing of all of said plurality of slave units via a tail slave of said daisy chain.

6. The electronic system of claim 5, wherein all of said master processor and said slaves operate based on a common clock provided by said test equipment,
wherein said master processor receives a plurality of packets containing said data units and instructions for testing all of said plurality of functional blocks,
wherein said master processor communicates with said slaves in form of a sequence of packets to transmit said data units to respective slaves according to a convention.

7. The electronic system of claim 6, wherein said convention comprises specifying a number packets that will carry said data units, number of slots in each packet, and allocation of each slot to one slave,
wherein said master communicates said convention to said plurality of slaves, whereby each slave receives corresponding data units from its allocated slots.

8. The electronic system of claim 7, wherein said master processor receives a set of dynamically generated identifiers (ID) for said plurality of slave units from said test equipment,
said master processor to configure a plurality of sets of single-bit storage elements forming slave-ID registers of said slave units as a shift register,
said master to shift bits of said set of dynamically generated identifiers into said shift register in a single-pass operation.

9. The electronic system of claim 8, wherein each slave comprises registers indicating number of slots per packet, allocation of slots to itself, and total number of packets for a test session,
wherein said master first sends a slave identifier followed by respective values for said registers in the slave having the slave identifier.

10. The electronic system of claim 9, wherein a first slot is allocated to said first slave unit in a first number of packets of said test session and then reallocated to said second slave unit according to said convention when test performed on said second slave unit in said test session is completed based on said first number of packets.

11. The electronic system of claim 10, wherein said electronic system comprises a plurality of Systems-on-Chip (SOCs), wherein each SOC comprises a respective master processor, a respective plurality of slave units, a respective plurality of functional blocks, and a respective plurality of bridges,
wherein said plurality of masters are connected in a second daisy chain such that said test equipment sends packets to all of said plurality of masters via a head master of said second daisy chain and receive results of testing functional blocks in all of said plurality of masters via a tail master of said second daisy chain.

12. The electronic system of claim 11, wherein tests are performed concurrently across functional blocks of all of said plurality of SOCs.

13. The electronic system of claim 11, wherein each master processor is operable in a bypass-mode in which the master processor merely forwards received packets to a next master processor in said second daisy chain without processing said received packets in duration when no test is being performed on any functional block associated with the master processor.

14. The electronic system of claim 10, wherein the signal interface between said test equipment and said master processor comprises a first data bus, a second data bus, a mode signal, a control signal and said common clock,
wherein said first data bus transfers a first set of packets from said test equipment to said master processor, wherein said test instructions and said data units are comprised in said first set of packets,
wherein said second data bus transfers a second set of packets from said master processor to said test equipment, wherein said results are comprised in said second set of packets,
wherein said mode signal is a RESET signal to RESET said master processor and said plurality of slave units, and
wherein transitions in logic levels of said control signal cause said master processor to fetch, decode and execute said test instructions.

15. The electronic system of claim 14, wherein the signal interface between said master processor and said head slave comprises a first slave data bus, a command bus, and a slave-ID serial path,
wherein said first slave data bus transfers a first said of data units comprised in said first set of packets from said master processor to said head slave,
wherein said command bus transfers commands generated by said master processor in response to corresponding test instructions in said first set of packets to said head slave, and wherein said master processor shift bits of said set of dynamically generated identifiers via said slave-ID serial path,
wherein the signal interface between said master processor and said tail slave comprises a second slave data bus, wherein said second slave data bus transfers said results from said tail slave to said master processor.

16. The electronic system of claim 15, wherein said first slave unit is operable in a bypass-mode in which said first slave merely forwards received data units to a next slave in said first daisy chain without processing said received data units in duration when no test is being performed on said first slave.

17. A non-transitory machine-readable medium storing one or more sequences of instructions for testing of an electronic system comprising a plurality of functional blocks and a plurality of slave units, wherein each functional block is coupled to a corresponding slave unit for being tested, wherein execution of said one or more instructions by one or more processors contained in a test equipment cause said test equipment to perform the actions of:
sending test instructions and data units as a basis for a plurality of tests to a master unit, wherein said test equipment indicates a corresponding slave unit to which each test is directed to,
said master processor forwarding test instructions and each data unit corresponding to each test of said plurality of tests to a respective slave unit as indicated by said test equipment,
wherein each slave unit executes corresponding test on the coupled functional block.

18. The non-transitory machine-readable medium of claim 16, wherein said sending comprises:
sending a first set of test instructions and a first set of data units as a basis for a first test directed to a first slave unit starting from a first time instance and said first slave unit completes executing said first test by a second time instance, wherein a first duration is constituted between said first time instance and said second time instance; and
sending a second set of test instructions and a second set of data units as a basis for a second test directed to a second slave unit starting from a third time instance and completes executing said second test by a fourth time instance, wherein a second duration is constituted between said third time instance and said fourth time instance,
wherein said first duration overlaps with said second duration such that first test is performed concurrent with said second test at least in part.

19. The non-transitory machine-readable medium of claim 18, wherein said plurality of slave units are connected sequentially in the form of a daisy chain, wherein the actions further comprise:
receiving for a test session, a test connectivity information, test data for testing all of said plurality of functional blocks, and a total number of packets, wherein said test connectivity information comprises a number and order of connectivity of slave units in said daisy chain; and
generating said test instructions and said data units as a basis for said plurality of tests, along with an indication of each slave to which each test is directed to.

20. The non-transitory machine-readable medium of claim 19, wherein a signal interface between said test equipment and said master processor comprises a first data bus, a second data bus, a mode output, a control path and a clock path for said common clock, said actions further comprising:
transferring a first set of packets on said first data bus transfers from said test equipment to said master processor, wherein said test instructions and said data units are comprised in said first set of packets;
transferring a second set of packets from said master processor to said test equipment on said second data bus, wherein said results are comprised in said second set of packets; and
issuing a RESET signal on said mode output to reset said master processor and said plurality of slave units,
wherein transitions in logic levels of a control signal on said control path cause said master processor to fetch, decode and execute said test instructions.
